(19) United States
(12) Patent Application Publication
(10) Pub. No.: US 2024/0145646 A1
(43) Pub. Date: May 2, 2024

(54) LIGHT EMITTING DEVICE

(71) Applicants: Citizen Electronics Co., Ltd., Fujiyoshida-shi (JP); Citizen Watch Co., Ltd., Tokyo (JP)

(72) Inventors: Kiyokazu WATANABE, Fujiyoshida-shi (JP); Yoshihito KITTA, Fujiyoshida-shi (JP); Yuichiro ANDO, Fujiyoshida-shi (JP); Katsuya AOSHIMA, Fujiyoshida-shi (JP); Ryo MATSUURA, Fujiyoshida-shi (JP); Kohki UENO, Fujiyoshida-shi (JP)

(21) Appl. No.: 18/404,050

(22) Filed: Jan. 4, 2024

Related U.S. Application Data
(63) Continuation of application No. PCT/JP2022/027159, filed on Jul. 8, 2022.

(30) Foreign Application Priority Data
Jul. 8, 2021 (JP) 2021-113809
Jan. 11, 2023 (JP) 2023-002592

(51) Int. Cl. H01L 33/56; H01L 25/075; H01L 33/54; H01L 33/62

(52) U.S. Cl. CPC H01L 33/56; H01L 25/0753; H01L 33/54; H01L 33/62

(57) ABSTRACT

The light emitting device has a substrate, a light emitting element arranged on the top surface of the substrate, a frame body arranged on the top surface of the substrate so as to surround the light emitting element and reflecting light from the light emitting body, and a sealing material arranged inside the frame body and sealing the light emitting element, and the frame body has a first frame portion having a first inner circumferential curved surface protruding to the side of the light emitting element and a second frame portion having a second inner circumferential curved surface, and a connection portion of the first frame portion and the second frame portion is arranged so as to have the same height as that of the top surface of the light emitting element.

### CROSS-REFERENCE TO RELATED APPLICATION

This application is a U.S. Bypass Continuation of PCT Application No. PCT/JP2022/027159, filed Jul. 8, 2022, which is based upon and claims the benefit of priority of prior Japanese Patent Application No. 2021-113809, filed on Jul. 8, 2021, and prior Japanese Patent Application No. 2023-002592, filed on Jan. 11, 2023, the entire contents of which are incorporated herein by reference.

### FIELD

The present disclosure relates to a light emitting device.

### BACKGROUND

A packaged light emitting device is known, which mounts a light emitting element, such as an LED (Light Emitting Diode), and an electrode and wiring for supplying electric power to the light emitting element on a substrate. In the light emitting device such as this, improvement of extraction efficiency of light from the light emitting element is demanded.

Japanese Unexamined Patent Publication No. 2008-41290 has described that in a light emitting device in which a plurality of frame bodies reflecting light from a light emitting element is arranged on a substrate in an overlapping manner so as to surround the light emitting element, the light emitted laterally from the light emitting element is reflected from the frame body and extracted to the outside of the light emitting device.

### SUMMARY

It is desirable for light as uniform as possible and as much as possible to be emitted from the light emitting surface of the light emitting device. Thus, when the frame body is provided in the light emitting device, part of light emitted from the light emitting element is reflected from the frame body, and when the frame body has only a uniform surface, the reflection direction is limited and light extraction efficiency may be reduced.

Thus, the frame body may be formed by a plurality of curved surfaces as described in Japanese Unexamined Patent Publication No. 2008-41290. However, much of the light emitted from the light emitting element, such as an LED, is emitted from the vicinity of the top surface thereof. Thus, if the reflection surface of the frame body at substantially the same height as the top surface of the light emitting element is configured by only uniform surfaces, even though the reflection surface of the frame body is configured by a plurality of curved surfaces, light extraction efficiency may not be considerably improved.

The present disclosure has been made in order to solve the above-described problem and an object thereof is to provide a light emitting device enabling improvement of light extraction efficiency by configuring a frame body by a plurality of curved surfaces and then, arranging a connection portion between curved surfaces at substantially the same height as that of the top surface of a light emitting element.

The light emitting device according to the present disclosure has a substrate, a light emitting element arranged on the top surface of the substrate, a frame body arranged on the top surface of the substrate so as to surround the light emitting element and reflecting light from the light emitting element, and a sealing material arranged inside the frame body and sealing the light emitting element, and the frame body has a first frame portion having a first inner circumferential curved surface protruding to the side of the light emitting element and a second frame portion having a second inner circumferential curved surface protruding to the side of the light emitting element, and the first inner circumferential curved surface and the second inner circumferential curved surface each have the shape of a cross section convex upward, and the connection portion of the first frame portion and the second frame portion is arranged so as to have the same height as that of the top surface of the light emitting element.

Further, in the light emitting device according to the present disclosure, it is preferable for the inclination angle of the first inner circumferential curved surface in the connection portion to be smaller than the inclination angle of the second inner circumferential curved surface in the connection portion.

Further, in the light emitting device according to the present disclosure, it is preferable for the difference between the height of the connection portion from the surface of the substrate and the height of the top surface of the light emitting element from the surface of the substrate to be less than or equal to ±10% of the height of the top surface of the light emitting element from the surface of the substrate.

Further, in the light emitting device according to the present disclosure, it is preferable for the distance from the light emitting element to the connection portion to be less than or equal to 300 μm.

Further, in the light emitting device according to the present disclosure, it is preferable for the ratio of the height of the second frame portion to the distance from the light emitting element to the connection portion to be not less than 0.2 and not more than 1.5.

Further, in the light emitting device according to the present disclosure, it is preferable for the second frame portion to be formed thicker than the first frame portion and cover the top portion and the outer circumferential surface of the first frame portion.

Further, in the light emitting device according to the present disclosure, it is preferable for the first frame portion and the second frame portion to include resin and titanium oxide and in the first frame portion and the second frame portion, for the content of titanium oxide with resin taken as a reference to be not less than 30 phr and not more than 130 phr.

Further, it is preferable for the light emitting device according to the present disclosure to further have an electrically conductive wiring pattern arranged so as to be surrounded by the frame body on the top surface of the substrate and reflecting light from the light emitting element, for the light emitting element to be arranged on the top surface of the wiring pattern and, for the frame body to cover the outer circumferential portion of the wiring pattern.

Further, in the light emitting device according to the present disclosure, it is preferable for first wiring and second wiring electrically connected to the light emitting element to be arrayed along the long-side direction of the substrate on the substrate as well as for the substrate to have the shape of a rectangular plane, and for the width of the frame body arranged at both ends in the long-side direction of the substrate to be greater than the width of the frame body arranged at both ends in the short-side direction of the substrate, and for the top surface of the sealing material to have the shape of a square plane.

Further, in the light emitting device according to the present disclosure, it is preferable for the separation distance between the front end of the first frame portion arranged in the long-side direction of the substrate and the light emitting element to be longer than the separation distance between the front end of the first frame portion arranged in the short-side direction of the substrate and the light emitting element.

Further, in the light emitting device according to the present disclosure, in the short-side direction of the substrate, it is preferable for the length obtained by adding the separation distance between the front end of one of a pair of the first frame portions facing each other and the end portion of the substrate and the separation distance between the front end of the other of the pair and the end portion of the substrate to be longer than the length obtained by adding the separation distance between the front end of one of the pair of the first end portions facing each other and the light emitting element and the separation distance between the front end of the other of the pair and the light emitting element.

Further, the light emitting device according to the present disclosure has a substrate on the top surface of which a wiring pattern in which a concave portion is formed is arranged, a light emitting element arranged on the top surface of the substrate, a frame body arranged on the top surface of the substrate so as to surround the light emitting element, and a sealing material arranged inside the frame body and sealing the light emitting element, and the frame body at least has a first frame portion having a first inner circumferential curved surface protruding to the side of the light emitting element and a second frame portion having a second inner circumferential curved surface protruding to the side of the light emitting element, the first inner circumferential curved surface and the second inner circumferential curved surface each have the shape of a cross section convex upward, the connection portion of the first frame portion and the second frame portion is arranged so as to have the same height as that of the top surface of the light emitting element, on the substrate, the first wiring and the second wiring electrically connected to the light emitting element are arrayed along the long-side direction of the substrate as well as the substrate has the shape of a rectangular plane, the width of the frame body arranged at both ends in the long-side direction of the substrate is greater than the width of the frame body arranged at both ends in the short-side direction of the substrate, and the pair of the first frame portions arranged in the long-side direction of the substrate is arranged so as to cover the concave portion.

The light emitting device according to the present disclosure may improve light extraction efficiency.

### BRIEF DESCRIPTION OF DRAWINGS

FIG. 1 is a plan diagram of a light emitting device according to a first embodiment;

FIG. 2 is a cross-sectional diagram (part 1) of the light emitting device shown in FIG. 1;

FIG. 3 is a cross-sectional diagram (part 2) of the light emitting device shown in FIG. 1;

FIG. 4 is diagram for explaining a relationship between the height of a connection portion and the height of a top surface of a light emitting element shown in FIG. 2;

FIG. 5 is a diagram showing a relationship between the height of the connection portion shown in FIG. 2 and the intensity of light emitted to the outside of the light emitting device shown in FIG. 1;

FIG. 6 is a diagram for explaining the distance from the light emitting element to the connection portion shown in FIG. 1;

FIG. 7 is a diagram for explaining the height of a second frame portion shown in FIG. 2;

FIG. 8 is a diagram showing a relationship between the height of the second frame portion shown in FIG. 2 and the intensity of light emitted to the outside of the light emitting device shown in FIG. 1;

FIG. 9 is a diagram for explaining a relationship between a first inner circumferential curved surface and a second inner circumferential curved surface in the connection portion shown in FIG. 2;

FIG. 10 is a diagram for explaining a relationship between the first inner circumferential curved surface and the second inner circumferential curved surface;

FIG. 11A is a diagram showing chromaticity uniformity of the light emitting device shown in FIG. 1 and FIG. 11B is a diagram showing chromaticity uniformity of a comparative example;

FIG. 12 is a flow diagram showing an example of a flow of a manufacturing method of the light emitting device shown in FIG. 1;

FIG. 13A-13E are schematic diagrams for explaining each process of the manufacturing method of the light emitting device shown in FIG. 1;

FIG. 14 is a diagram for explaining the content of titanium oxide in the frame body shown in FIG. 1;

FIG. 15 is a plan diagram of a light emitting device according to a second embodiment;

FIG. 16 is a cross-sectional diagram of the light emitting device shown in FIG. 15;

FIG. 17 is a plan diagram of a light emitting device according to a third embodiment;

FIG. 18 is a cross-sectional diagram (part 1) of the light emitting device shown in FIG. 17;

FIG. 19 is a cross-sectional diagram (part 2) of the light emitting device shown in FIG. 17;

FIG. 20 is a cross-sectional diagram of a light emitting device according to a fourth embodiment;

FIG. 21 is a plan diagram of a light emitting device according to a fifth embodiment;

FIG. 22 is a cross-sectional diagram of the light emitting device shown in FIG. 21;

FIG. 23 is a plan diagram of a light emitting device according to a sixth embodiment;

FIG. 24 is a cross-sectional diagram of the light emitting device shown in FIG. 23;

FIG. 25 is a plan diagram (part 1) of a light emitting device according to a seventh embodiment;

FIG. 26 is a cross-sectional diagram (part 2) of the light emitting device shown in FIG. 25;

FIG. 27 is a plan diagram of a light emitting device according to an eighth embodiment;

FIG. 28 is a cross-sectional diagram (part 1) of the light emitting device shown in FIG. 27;

FIG. 29 is a cross-sectional diagram (part 2) of the light emitting device shown in FIG. 27;

FIG. 30 is a plan diagram of a light emitting device according to a ninth embodiment;

FIG. 31 is a cross-sectional diagram (part 1) of the light emitting device shown in FIG. 30;

FIG. 32 is a cross-sectional diagram (part 2) of the light emitting device shown in FIG. 30;

FIG. 33 is a plan diagram of a light emitting device according to a tenth embodiment;

FIG. 34 is an enlarged diagram of a portion surrounded by a broken line A shown in FIG. 33;

FIG. 35 is a diagram for explaining a relationship between the blend amount of first particle diameter filler and hardness;

FIG. 36 is a diagram for explaining a relationship between the blend amount of second particle diameter filler and viscosity;

FIG. 37 is a diagram for explaining preferable arrangement in the short-side direction in a light emitting device according to an embodiment; and

FIG. 38A is a diagram (part 1) showing directivity when the separation distance between the front end of the first frame portion and the end portion of the light emitting element is changed, FIG. 38B is a diagram (part 2) showing directivity when the separation distance between the front end of the first frame portion and the end portion of the light emitting element is changed, FIG. 38C is a diagram (part 3) showing directivity when the separation distance between the front end of the first frame portion and the end portion of the light emitting element is changed, FIG. 38D is a diagram (part 4) showing directivity when the separation distance between the front end of the first frame portion and the end portion of the light emitting element is changed, FIG. 38E is a diagram (part 5) showing directivity when the separation distance between the front end of the first frame portion and the end portion of the light emitting device is changed, FIG. 38F is a diagram (part 6) showing directivity when the separation distance between the front end of the first frame portion and the end portion of the light emitting element is changed, and FIG. 38G is a diagram (part 7) showing directivity when the separation distance between the front end of the first frame portion and the end portion of the light emitting element is changed.

### DESCRIPTION OF EMBODIMENTS

In the following, with reference to the drawings, a variety of embodiments of the present disclosure are explained. It should be noted that the technical scope of the present disclosure is not limited to those embodiments, but encompasses the invention described in the claims and equivalents thereof.

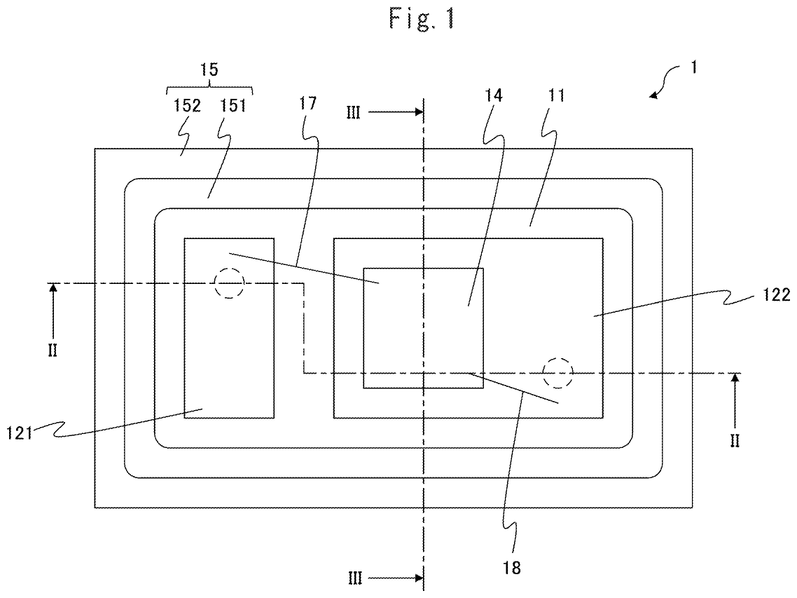

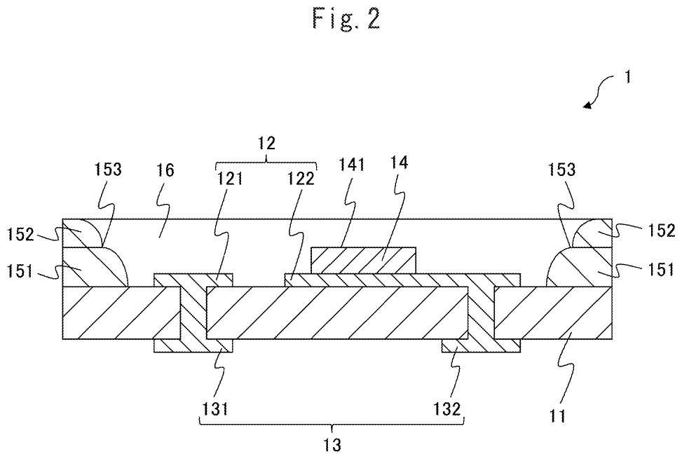

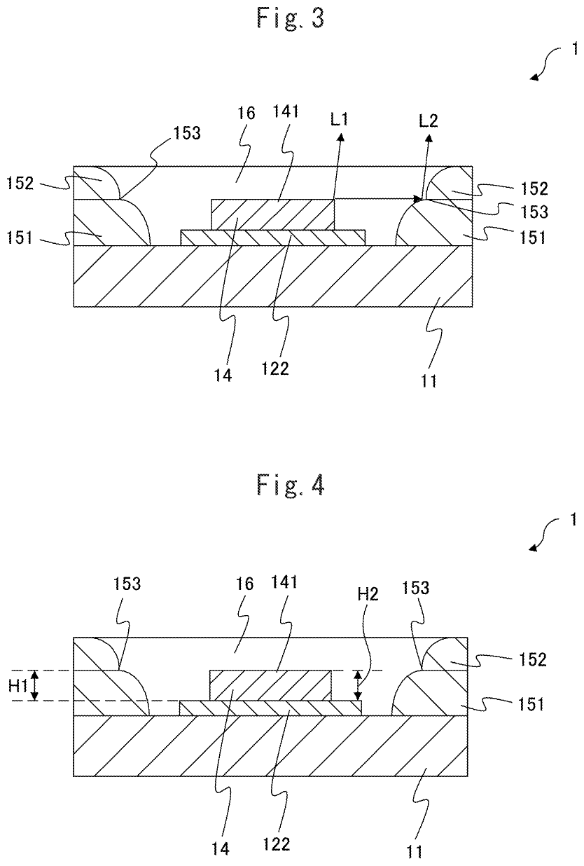

FIG. 1 is a plan diagram of a light emitting device according to the first embodiment and FIGS. 2 and 3 are each a cross-sectional diagram of a light emitting device 1. FIG. 2 is a cross-sectional diagram along a II-II line in FIGS. 1 and 3 is a cross-sectional diagram along a line in FIG. 1. the upper side in FIG. 2 and FIG. 3 is referred to as an upper side of the light emitting device 1, while the lower side is referred to as a lower side of the light emitting device 1.

The light emitting device 1 has a substrate 11, a wiring pattern 12, an electrode 13, a single light emitting element 14, a frame body 15, and a sealing material 16.

The substrate 11 is formed of an electrically insulating resin, such as a phenol resin, an epoxy resin, a polyimide resin, or a polyester resin into the shape of a rectangular flat plate. The thickness of the substrate 11 is, for example, 200 μm.

The wiring pattern 12 has first wiring 121 and second wiring 122 both in the shape of a flat plate provided on the top surface of the substrate 11 separate from each other. The first wiring 121 and the second wiring 122 each have the shape of a rectangular plane and are formed of silver. The first wiring 121 and the second wiring 122 each have an area in which a boding wire may be arranged, which is capable of being electrically connected with the light emitting element 14 by wire boding processing. Further, the separation distance between the first wiring 121 and the second wiring 122 has a length greater than or equal to an insulation distance. The substrate 11 has the shape of a rectangular plane whose long-side direction is the array direction of the first wiring 121 and the second wiring 122, by securing the area in which the boding wire may be arranged by the first wiring 121 and the second wiring 122, and separating a distance between the first wiring 121 and the second wiring 122 longer than or equal to the insulation distance. In the example shown in FIG. 1, the first wiring 121 and the second wiring 122 are arrayed side by side along the long-side direction of the substrate 11. The thickness of the first wiring 121 and the second wiring 122 is, for example, 50 μm. The wiring pattern 12 may be formed of a material having another electrical conductivity, which reflects light from the light emitting element 14, including gold, copper, or aluminum.

The electrode 13 has a first electrode 131 and a second electrode 132 which are provided on the under surface of the substrate 11 with separating each other. The first electrode 131 and the second electrode 132 are each formed of an electrical conductor, such as gold or copper. The first electrode 131 is electrically connected with the first wiring 121 via a through hole (in FIG. 1, schematically shown by a broken line) penetrating vertically through the substrate 11. Similarly, the second electrode 132 is electrically connected with the second wiring 122 via a through hole (in FIG. 1, schematically shown by a broken line) penetrating vertically through the substrate 11. The first electrode 131 and the second electrode 132 are connected with an external power supply, not shown schematically, and used for supplying electric power to the light emitting element 14 via the wiring pattern 12.

The light emitting element 14 is fixed to the top surface of the second wiring 122 by die bond, such as silver paste and solder as shown in FIGS. 1 to 3. The light emitting element 14 is, for example, a blue LED emitting light whose wavelength is 440 to 455 nm and consisting of an InGaN-based compound semiconductor. On a top surface 141 of the light emitting element 14, a pair of element electrodes is provided and a first element electrode is connected with the first wiring 121 via a boding wire 17 and a second element electrode is connected with the second wiring 122 via a boding wire 18.

The light emitting element 14 has, for example, the shape of substantially a parallelepiped whose each of vertical and horizontal sides is 650 μm and whose height is 260 μm. The light emitting element 14 emits light in response to an electric current being supplied between the first wiring 121 and the second wiring 122 from an external power supply. The light emitting element 14 is not limited to the blue LED and for example, may be a purple LED or a near-ultraviolet LED and the light emission wavelength band may be within a range about 200 to 440 nm including the ultraviolet band.

The frame body 15 is arranged in the shape of a rectangle along the outer circumference of the substrate 11 on the top surface of the substrate 11 so as to surround the light emitting element 14, the first wiring 121, and the second wiring 122. The frame body 15 is a white resin formed by dispersing fine particles of titanium oxide (TiO₂) in a resin, such as a silicon resin or an epoxy resin, and reflects light from the light emitting element 14.

The frame body 15 has a first frame portion 151 having a first inner circumferential curved surface protruding to the side of the light emitting element 14 and a second frame portion 152 connecting to the top portion of the first frame portion 151 and having a second inner circumferential curved surface protruding to the side of the light emitting element 14. In other words, the frame body 15 has the shape in which the second frame portion 152 is stacked on the first frame portion 151. A connection portion 153 between the first frame portion 151 and the second frame portion 152 is arranged so as to have the same height as that of the top surface 141 of the light emitting element 14. When the height of the connection portion 153 from the surface of the substrate 11 is less than or equal to ±10% of the height of the top surface 141 of the light emitting element 14 from the surface of the substrate 11, the height of the connection portion 153 and the height of the top surface 141 of the light emitting element 14 are regarded as the same. In the example shown in FIG. 2 and FIG. 3, each of the first inner circumferential curved surface and the second inner circumferential curved surface has the shape of a cross section convex upward.

Further, the width in the transverse direction of the second frame portion 152 is less than the width in the transverse direction of the first frame portion 151. In other words, the second frame portion 152 is formed thinner than the first frame portion 151. The light emission area (referring to the area of the top surface of the sealing material 16) of the light emitting device 1 is large and the light extraction efficiency of the light emitting device 1 improves, by forming the second frame portion 152 thinner than the first frame portion 151.

The sealing material 16 is a translucent resin, such as an epoxy resin or a silicon resin. The sealing material 16 is filled up to the height at which at least the top surface 141 of the light emitting element 14 is not exposed in the area surrounded by the frame body 15, and therefore the sealing material 16 seals the light emitting element 14. The sealing material 16 is mixed with a fluorescent substance converting the wavelength of light from the light emitting element 14. The sealing material 16 is mixed with a yellow fluorescent substance, such as YAG (Yttrium Aluminum Garnet), as the fluorescent substance. The light emitting device 1 emits white light obtained by blue light from the light emitting element 14, which is a blue LED, and yellow light obtained by the blue light exciting the yellow fluorescent substance being mixed. FIGS. 1 to 3 are shown schematically on the assumption that the sealing material 16 is transparent and this is the same in the following.

The yellow fluorescent substance described previously is one example and the sealing material 16 may contain another fluorescent substance. For example, the sealing material 16 may contain two kinds of fluorescent substance: a green fluorescent substance and a red fluorescent substance. The light emitting device 1 emits white light obtained by mixing blue light from the light emitting element 14, which is a blue LED, and green light and red light obtained by exciting the green fluorescent substance and the red fluorescent substance by the blue light. A fluorescent substance material in the shape of particles, such as (BaSr)₂SiO4:Eu²⁺ may be used as the green fluorescent substance, which absorbs blue color emitted by the light emitting element 14 and wavelength-converts the blue light into green light. A fluorescent substance material in the shape of particles, such as CaAlSiN₃:Eu²⁺ may be used as the red fluorescent substance, which absorbs blue light emitted by the light emitting element 14 and wavelength-converts the blue light into red light.

The green fluorescent substance and the red fluorescent substance described previously are each one example and the sealing material 16 may add a small amount of green fluorescent substance and a small amount of red fluorescent substance to the yellow fluorescent substance described previously. White light is obtained as a reference by mixing the blue light from the light emitting element 14, which is a blue LED, and the yellow light obtained by exciting the yellow fluorescent substance by the blue light, though color rendering properties of the white light are inferior to those of the combination described previously, the light emitting device 1 may emit white light whose color rendering properties are improved by mixing the green light and the red light similarly excited.

As shown in FIG. 3, light L1 emitted upward from the light emitting element 14 is transmitted through the sealing material 16 and emitted to the outside of the light emitting device 1. Light L2 emitted laterally from the vicinity of the top surface 141 of the light emitting element 14 reaches the vicinity of the connection portion 153 of the frame body 15. In the connection portion 153, the inclination angle of the inner circumferential surface of the first frame portion 151 is small, and therefore, the light L2 is reflected upward at the first frame portion 151, and emitted to the outside of the light emitting device 1. When the inclination angle of the inner circumferential surface of the frame body 15 in the connection portion 153 is large, the light emitted laterally from the light emitting element 14 is reflected toward the direction of the frame body 15 in opposition thereto, not upward, the light is reflected repeatedly a plurality of times between the light emitting element 14 and the frame body 15 in opposition thereto, and the light is emitted to the outside of the light emitting device 1. The light attenuates considerably due to the plurality of times of reflection, and therefore the light extraction efficiency of the light emitting device 1 is reduced. Since the inclination angle of the inner circumferential surface of the first frame portion 151 in the connection portion 153 is formed small in the frame body 15, the light emitted laterally from the light emitting element 14 is emitted to the outside of the light emitting device 1 by one-time reflection, and therefore the light extraction efficiency improves.

Further, much of the light emitted laterally from the light emitting element 14 is emitted from the vicinity of the top surface 141 of the light emitting element 14. Since the connection portion 153 is located at the same height as that of the top surface 141 of the light emitting element 14 in the frame body 15, much of the light emitted laterally from the light emitting element 14 is emitted to the outside of the light emitting device 1 by one-time reflection, and therefore the light extraction efficiency further improves.

FIG. 4 is a diagram for explaining a relationship between the height of the connection portion 153 and the height of the top surface 141 of the light emitting element 14. FIG. 4 is a cross-sectional diagram at the same cross section as that in FIG. 3. The height of the connection portion 153 refers to a height H1 of the connection portion 153 from the top surface of the wiring pattern 12 as shown in FIG. 4. The height of the top surface 141 of the light emitting element 14 refers to a height H2 of the top surface 141 of the light emitting element 14 from the top surface of the wiring pattern 12.

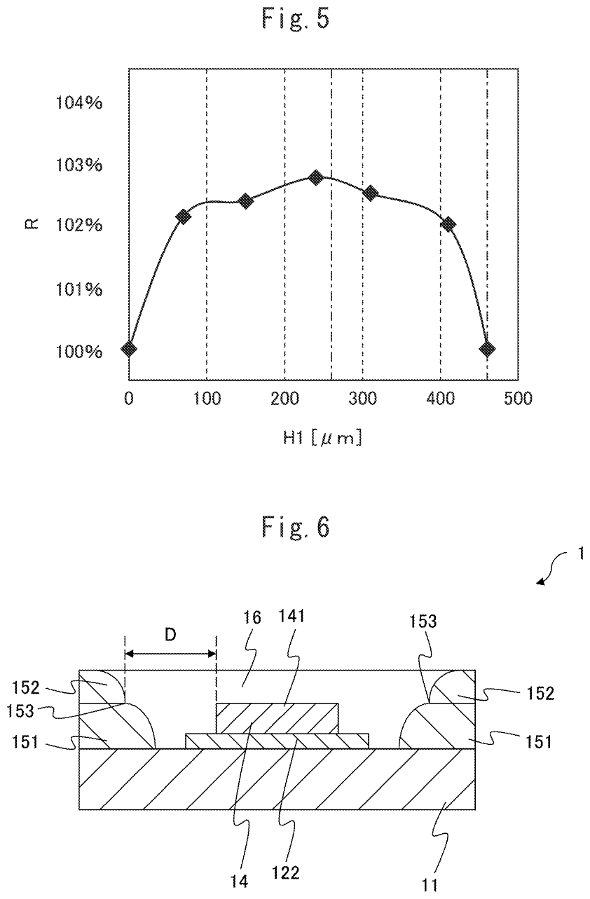

FIG. 5 is a diagram showing a relationship between the height of the connection portion 153 and the intensity of light emitted to the outside of the light emitting device 1. In the graph in FIG. 5, the horizontal axis represents the height H1 of the connection portion 153 from the top surface of the wiring pattern 12 and the vertical axis represents an intensity ratio R of light emitted to the outside of the light emitting device 1. The intensity ratio R is an intensity ratio in which the intensity of light emitted to the outside of the light emitting device 1 is 100% when the height H1 of the connection portion 153 is 0 μm (i.e., the height of the connection portion 153 is equal to the height of the top surface of the wiring pattern 12). The data shown in the graph in FIG. 5 is obtained as the height H2 of the top surface 141 of the light emitting element 14 is 260 μm, and the height of the frame body 15 is 460 μm. Further, in FIG. 5, the height H2 of the top surface 141 of the light emitting element 14 and the height of the frame body 15 are each indicated by a one-dot chain line.

As shown in FIG. 5, in the range in which the height H1 is substantially not less than 110 μm and not more than 410 μm, the intensity ratio R is 102% or more. Thus, in the range in which the difference between the height H1 of the connection portion 153 and the height H2 of the top surface 141 of the light emitting element 14 is less than or equal to 150 μm, the intensity of the light emitted to the outside of the light emitting device 1 is large by 2% or more, and therefore, the light extraction efficiency improves.

Further, in the range in which the height H1 is substantially not less than 230 μm and not more than 290 μm, the intensity ratio R further improves than that in the range in which the height H1 is substantially not less than 110 μm and not more than 410 μm. Thus, in the range in which the difference between the height H1 of the connection portion 153 and the height H2 of the top surface 141 of the light emitting element 14 is ±10% of the height H1 of the connection portion 153, the intensity of the light emitted to the outside of the light emitting device 1 becomes further large and the light extraction efficiency further improves.

FIG. 6 is a diagram for explaining the distance from the light emitting element 14 to the connection portion 153. FIG. 6 is a cross-sectional diagram at the same cross section as that in FIG. 3. A distance D from the light emitting element 14 to the connection portion 153 refers to the distance in the horizontal direction between the lateral surface facing the frame body 15 of the light emitting element 14 and the connection portion 153 as shown in FIG. 6. It is preferable for the distance D to be less than or equal to 300 μm and further preferable to be less than or equal to 200 μm. The shorter the distance D from the light emitting element 14 to the connection portion 153, the smaller the amount of attenuation until the light emitted laterally from the light emitting element 14 reaches the connection portion 153 is, and therefore the intensity of the light emitted to the outside of the light emitting device 1 is high and the light extraction efficiency further improves. Although the light emitting element 14 is arranged in the center of the frame body 15 in the example shown in FIGS. 1 to 3, the arrangement is not limited to such an example. The light emitting element 14 may be arranged at an arbitrary position inside the frame body 15 so that the distance D between at least one lateral surface of the four lateral surfaces of the light emitting element 14 and the frame body 15 facing the lateral surface is 300 μm or less.

Further, since the distance D from the light emitting element 14 to the connection portion is 153 to 300 μm or less, the area filled with the sealing material 16 is small, and therefore the amount of the necessary resin and fluorescent substance is reduced and the manufacturing cost may be reduced.

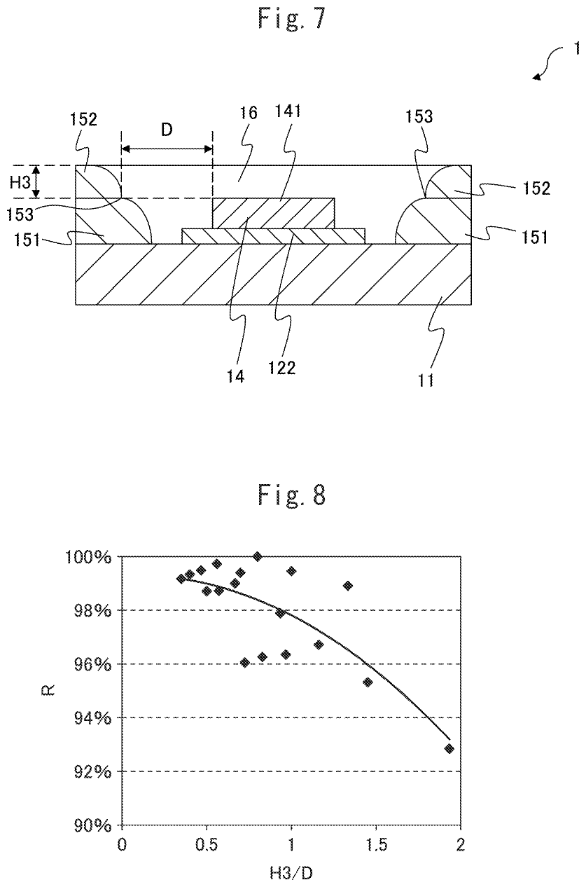

FIG. 7 is a diagram for explaining the height of the second frame portion 152. FIG. 7 is a cross-sectional diagram at the same cross section as that in FIG. 3. The height of the second frame portion 152 refers to a height H3 of the vertex portion of the second frame portion 152 from the height of the connection portion 153.

FIG. 8 is a diagram showing a relationship between the height of the second frame portion 152 and the intensity of light emitted to the outside of the light emitting device 1. In the graph in FIG. 8, the horizontal axis represents a ratio H3/D, the height H3 of the second frame portion 152 to the distance D from the light emitting element 14 to the connection portion 153, and the vertical axis represents the intensity ratio R of light emitted to the outside of the light emitting device 1. The data shown in FIG. 8 is obtained by appropriately changing the height of the second frame portion 152, and changing the distance D from the light emitting element 14 to the connection portion 153 in the range between 150 μm and 400 μm. The intensity ratio R is the ratio of light in which the largest intensity of light among the data obtained by the above-described method is 100%.

As shown in FIG. 8, when H3/D is 0.8, the intensity ratio R is the maximum and as H3/D is large, the intensity ratio R decreases. Further, when H3/D is larger than 1.5, the intensity ratio R is less than 95%. Thus, the light extraction efficiency improves, by setting H3/D to 1.5 or less, and when the height H3 of the second frame portion 152 is low, the top surface of the light emitting element and the top surface of the sealing material 16 are close to each other, and therefore the fluorescent substance of the sealing material 16 is not excited sufficiently and white light may be no longer obtained. Thus, it is preferable to set H3/D to 0.2 or more.

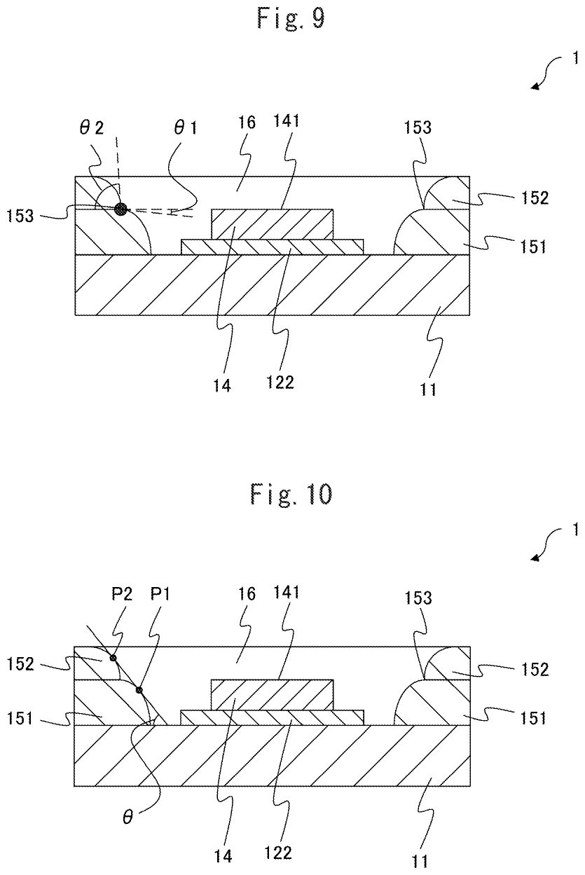

FIG. 9 is a diagram for explaining a relationship between the first inner circumferential curved surface and the second inner circumferential curved surface in the connection portion 153. An inclination angle θ1 shown in FIG. 9 is the inclination angle of the first inner circumferential curved surface in the connection portion 153, i.e., the angle formed by the tangential plane tangent to the inner circumferential curved surface of the first frame portion 151 in the connection portion 153 and the substrate 11. Further, an inclination angle θ2 is the inclination angle of the second inner circumferential curved surface in the connection portion 153, i.e., the angle formed by the tangential plane tangent to the inner circumferential curved surface of the second frame portion 152 in the connection portion 153 and the substrate 11. As shown in FIG. 9, the inclination angle θ1 is smaller than the inclination angle θ2.

Thus, the inclination of the lower side of the connection portion 153 is more gradual than the inclination of the upper side of the connection portion 153. The light emitted from the top surface 141 of the light emitting element 14 toward the lower side of the connection portion 153 is more likely to be reflected upward, by setting the inclination of the lower side of the connection portion 153 more gradual than the inclination of the upper side of the connection portion 153, and therefore the light extraction efficiency of the light emitting device 1 further improves.

FIG. 10 is a diagram for explaining a relationship between the first inner circumferential curved surface and the second inner circumferential curved surface. An inclination angle θ shown FIG. 10 is the inclination angle of the tangential plane tangent to the inner circumferential curved surface of the first frame portion 151 and the inner circumferential curved surface of the second frame portion 152, i.e., the angle formed by the plane tangent to the inner circumferential curved surface of the first frame portion 151 at a point of contact P1 and tangent to the inner circumferential curved surface of the second frame portion 152 at a point of contact P2 and the substrate 11. It is preferable for the inclination angle θ of the tangential plane tangent to the inner circumferential curved surface of the first frame portion 151 and the inner circumferential curved surface of the second frame portion 152 to be not less than 40 degrees and not more than 50 degrees and further preferable to be 45 degrees. Much of the light emitted in the horizontal direction from the light emitting element 14 is reflected vertically upward at the frame body 15, by setting the inclination angle θ of the tangential plane to not less than 40 degrees and not more than 50 degrees, and therefore the light extraction efficiency of the light emitting device 1 improves and at the same time, the spread of the light flux emitted to the outside from the light emitting device 1 is suppressed and the optical characteristics of the light emitting device 1 may improve.

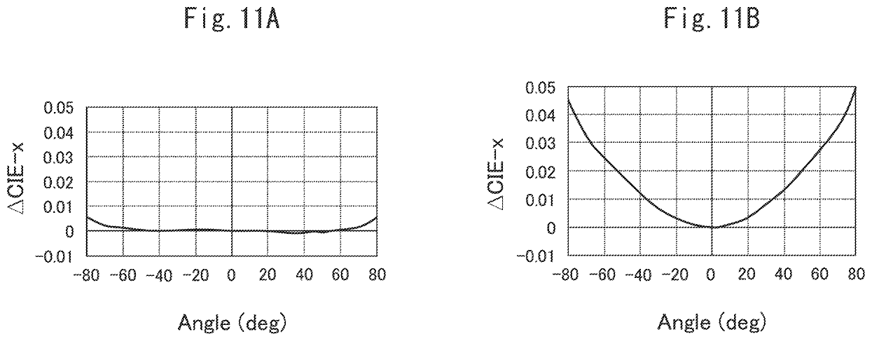

FIG. 11A is a diagram showing chromaticity uniformity in the light emitting device 1, and FIG. 11B is a diagram showing chromaticity uniformity in a comparative example. In the comparative example, as the inner circumferential surface of the frame body 15, a vertical surface is used in place of the inner circumferential curved surface protruding to the side of the light emitting element 14 in the light emitting device 1. Further, in the graph shown in FIG. 11A and FIG. 11B, the horizontal axis represents the angle with respect to the vertically upward direction of the emission direction of light in the short-side cross section (for example, cross section along line in FIG. 1) and the vertical axis represents the chromaticity difference from the light emitted vertically upward. The chromaticity difference is the difference of chromaticity x in the XYZ color space.

In FIG. 11B, as the emission angles increases, the chromaticity difference increases. Thus, FIG. 11B shows that a yellow ring occurs in the comparative example. On the other hand, in FIG. 11A, the chromaticity difference is substantially uniform in the range in which the emission angle is between −40 degrees and +40 degrees and even at −80 degrees and +80 degrees, the chromaticity difference is one fifth or less of that in the comparative example. Thus, FIG. 11A indicates that the yellow ring is suppressed in the light emitting device 1 and light with no color unevenness is emitted.

In the comparative example, the optical path length inside the sealing material 16 of the light emitted in the oblique direction from the light emitting element 14 is longer than that of the light emitted vertically upward. Thus, the light emitted in the oblique direction excites more fluorescent substances until it is emitted from the sealing material 16 and the color of the light becomes more yellowish than the color of the light emitted vertically upward, and therefore the yellow ring occurs. On the other hand, in the light emitting device 1, part of the light emitted in the oblique direction from the light emitting element 14 is reflected upward at the inner circumferential curved surface of the frame body 15. Thus, the emission direction of the yellowish light is made uniform on the whole, and therefore the yellow ring is suppressed.

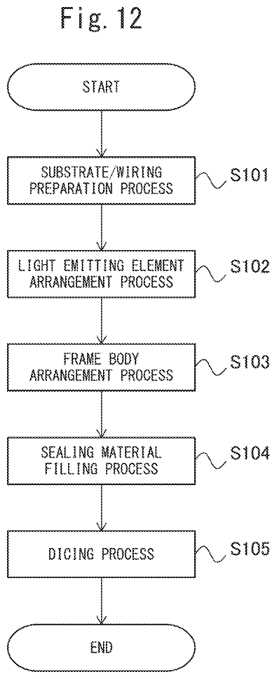

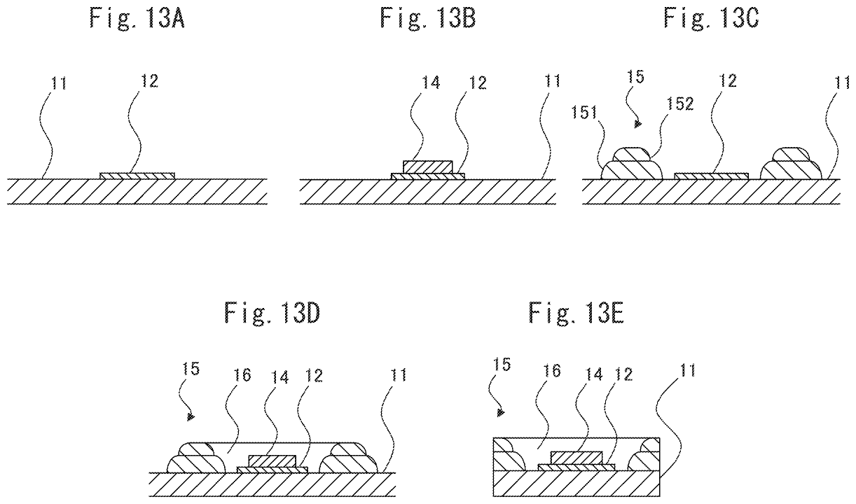

FIG. 12 is a flow diagram showing an example of a flow of a manufacturing method of the light emitting device 1 and FIG. 13A to 13E are each a schematic diagram for explaining each process of the manufacturing method of the light emitting device 1. In the following, although the manufacturing method for manufacturing the one light emitting device 1 is explained, a plurality of the light emitting devices 1 may be manufactured at the same time, by using the manufacturing method explained in the following.

First, in a substrate/wiring preparation process, as shown in FIG. 13A, the substrate 11 on which the wiring pattern 12 and the electrode 13 are arranged in advance is prepared (step S101). The wiring pattern 12 and the electrode 13 are each arranged at a predetermined position on the top surface and the back surface of the substrate 11 by electroless silver plating and electrically connected to each other.

In a light emitting element arrangement process, as shown in FIG. 13B, the light emitting element 14 is arranged on the top surface of the second wiring 122 (step S102). Further, in the light emitting element arrangement process, the bonding wire 17 is arranged so as to connect the first element electrode of the light emitting element 14 and the second wiring 121 and the boding wire 18 is arranged so as to connect the second element electrode of the light emitting element 14 and the second wiring 122.

Next, in a frame body arrangement process, as shown in FIG. 13C, on the top surface of the substrate 11, the frame body 15 is arranged so as to surround the wiring pattern 12 and the light emitting element 14 (step S103). First, fine particles of titanium oxide are dispersed in thermosetting resin droplets, such as a silicon resin, and white resin droplets containing titanium oxide are prepared. Next, the white resin droplets are applied to the top surface of the substrate 11 so as to surround the wiring pattern 12 and the first frame portion 151 is formed by heating and hardening the applied resin droplets. At the time, the inner circumferential surface of the first frame portion 151 is a curved surface by the surface tension of the resin droplets. While the first frame portion 151 is hardening or after the first frame portion 151 hardens, by pressing the top surface of the first frame portion 151, the top surface of the first frame portion 151 is formed flat.

Following the above, the white resin droplets are further applied to the top surface of the first frame portion 151 formed flat, and the applied the resin droplets are heated and hardened, the second frame portion 152 is formed. At the time, the inner circumferential surface of the second frame portion 152 becomes a curved surface by the surface tension of the resin droplets. Further, the top surface of the first frame portion 151 is formed flat, and therefore the resin droplets are prevented from flowing down along the lateral surface of the first frame portion 151. While the second frame portion 152 is hardening or after the second frame portion 152 hardens, by pressing the top surface of the second frame portion 152, the top surface of the second frame portion 152 is formed flat. In this manner, the frame body 15 is arranged on the top surface of the substrate 11. For the frame body 15, it is not necessary to perform molding processing or cutting processing for forming the connection portion 153, and therefore the frame body 15 may be easily manufactured.

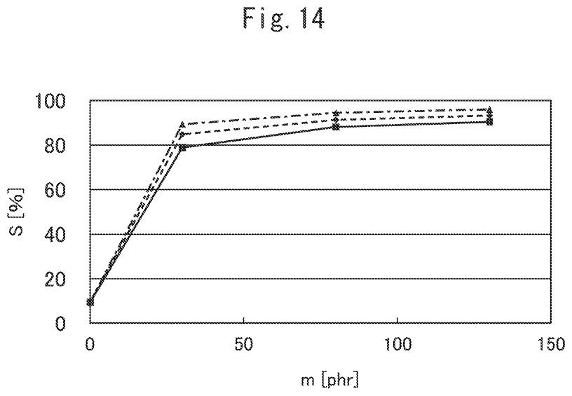

FIG. 14 is a diagram for explaining the content of titanium oxide in the frame body 15. In the graph in FIG. 14, the horizontal axis represents a content m of titanium oxide, with the resin in the frame body 15 as a reference, as the mass of titanium oxide with respect to mass 100 of resin, and the vertical axis represents reflectance S of the frame body 15. Further, in FIG. 14, data for 40 μm of the thickness of the frame body 15 is indicated by a solid line, data for 60 μm of the thickness is 60 μm is indicated by a broken line, and data for 100 μm of the thickness is indicated by a one-dot chain line, respectively.

As shown in FIG. 14, in each of the thickness, when the content m of titanium oxide is 0 phr (i.e., resin alone), the reflectance S of the frame body 15 is less than 10%, and when the content m is 30 phr, the reflectance S is substantially 80% or more. On the other hand, the amount of increase in the reflectance S is less than 10% when the content of titanium oxide is increased from 30 phr to 130 phr. Further, although not shown schematically, when the content m of titanium oxide is increased from 130 phr, a significant increase in reflectance is not observed. Thus, it is preferable for the content m of titanium oxide with resin as a reference to be not less than 30 phr and not more than 130 phr in the frame body 15, in order to improve the reflectance of the frame body 15.

As described above, when the first frame portion 151 and the second frame portion 152 are formed by applying resin droplets onto the top surface of the substrate 11, the ratio between width and height of each frame portion is determined by the viscosity of the resin droplets. Thus, the inclination angle θ shown in FIG. 10 is also determined by substantially the viscosity of the resin droplets. Then, the viscosity of the resin droplets changes in accordance with the content of titanium oxide. When the silicon resin is used as a resin, it is preferable that the content of titanium oxide is 60 phr, since the ratio between width and height of the frame body 15 is substantially 2:1 and the inclination angle θ is not less than 40 degrees and less than 50 degrees.

Returning to FIGS. 12 and 13, in a sealing material filling process, as shown in FIG. 13D, the area surrounded by the frame body 15 is filled with the sealing material 16 up to the height at which the top surface 141 of the light emitting element 14 is not exposed (step S104).

Lastly, in a dicing process, as shown in FIG. 13E, the frame body 15 and the substrate 11 are cut into the shape of a rectangle along the frame body 15, and the light emitting device 1 is manufactured (step S105). At the time, the top surface of the second frame portion 152 is formed flat, and therefore even if the cutting position shifts, the height of the cut frame body 15 is not affected by the shift and the light emitting device 1 with a uniform quality is manufactured.

As explained above, the light emitting device 1 has the light emitting element 14 arranged on the top surface of the substrate 11 and the frame body 15 arranged on the top surface of the substrate 11 so as to surround the light emitting element 14 and reflecting light from the light emitting element 14. Further, in the frame body 15, the connection portion 153 of the first frame portion 151 having the first inner circumferential curved surface protruding to the side of the light emitting element and the second frame portion 152 connecting to the top portion of the first frame portion 151 and having the second inner circumferential curved surface protruding to the side of the light emitting element is located at the same height as that of the top surface 141 of the light emitting element 14. The light emitting device 1 may improve the light extraction efficiency, by setting the height of the connection portion 153 to the same height as the top surface 141 of the light emitting element 14.

Further, in the light emitting device 1, the inclination angle of the first inner circumferential curved surface in the connection portion 153 is smaller than the inclination angle of the second inner circumferential curved surface in the connection portion 153, and therefore the light emitting device 1 may improve the light extraction efficiency.

Further, in the light emitting device 1, it is preferable for the difference between the height of the connection portion 153 and the height of the top surface 141 of the light emitting element 14 to be less than or equal to 100 μm. much of the light emitted laterally from the light emitting element 14 is emitted to the outside of the light emitting device 1 by one-time reflection, by setting the difference between the height of the connection portion 153 and the height of the top surface 141 of the light emitting element 14 to 100 μm or less, and therefore the light emitting device 1 may improve the light extraction efficiency.

Further, the light emitting device 1 may further improve the light extraction efficiency, by setting the difference between the height H1 of the connection portion 153 and the height H2 of the top surface 141 of the light emitting element 14 to ±10% or less of the height H1 of the connection portion 153.

Further, in the light emitting device 1, it is preferable for the distance from the light emitting element 14 to the connection portion 153 to be less than or equal to 300 μm. The optical path length through which the light emitted laterally from the light emitting element 14 travels until the light is emitted to the outside of the light emitting device 1 is short, by setting the distance from the light emitting element 14 to the connection portion 153 to 300 μm or less, and therefore the light emitting device 1 may further improve the light extraction efficiency.

Further, in the light emitting device 1, it is preferable for the inclination angle of the tangential plane tangent to the inner circumferential surface of the first frame portion 151 and the inner circumferential surface of the second frame portion 152 to be not less than 40 degrees and not more than 50 degrees. The light emitted laterally from the light emitting device 1 is more likely to travel toward the above of the light emitting device 1 by reflection, by setting the inclination angle of the tangential plane not less than 40 degrees and not more than 50 degrees, and therefore the light emitting device 1 may improve the optical characteristics as well as the light extraction efficiency.

Further, in the light emitting device 1, the frame body 15 includes resin and titanium oxide and the content of titanium oxide with respect to resin is not less than 30 phr and not more than 130 phr. The reflectance of the frame body 15 improves by setting the content of titanium oxide with respect to resin not less than 30 phr and not more 130 phr, and therefore the light emitting device 1 may further improve the light extraction efficiency.

Further, in the light emitting device 1, the second frame portion 152 is formed thinner than the first frame portion 151. The light emission area of the light emitting device 1 is large by forming the second frame portion 152 thinner than the first frame portion 151, and therefore the light emitting device 1 may further improve the light extraction efficiency.

Although, in the explanation explained above, the frame body 15 has the first frame portion 151 and the second frame portion 152, the frame body 15 may further have a third frame portion connecting to the top portion of the second frame portion 152. In the case, it is only necessary for one of the connection portion 153 of the first frame portion 151 and the second frame portion 152 and the connection portion of the second frame portion 152 and the third frame portion to be arranged at the same height as that of the top surface 141 of the light emitting element 14. Further, the frame body 15 may have the shape in which four or more frame portions are stacked one on top of another. Thus, it is only necessary for the frame body 15 to have at least the first frame portion 151 and the second frame portion 152.

In the explanation described above, although the light emitting element 14 is arranged on the top surface of the second wiring 122, the light emitting element 14 may be arranged on the top surface of the first wiring 121. Further, the light emitting element 14 may be arranged directly on the top surface of the substrate 11.

Although, in the explanation described above, the second frame portion 152 has the second inner circumferential curved surface protruding to the side of the light emitting element 14, the inner circumferential surface of the second frame portion 152 may be formed into the shape of a plane. Thus, only the inner circumferential surface of the first frame portion 151 may be the curved surface protruding to the side of the light emitting element 14. In the case, the light emitted laterally from the top surface 141 of the light emitting element 14 is reflected upward at the first inner circumferential curved surface, and therefore the light emitting device 1 may improve the light extraction efficiency.

Although, in the explanation described above, the shape of the frame body 15 is a rectangle, the shape is not limited to the example, and the shape of the frame body 15 may be arbitrary one surrounding the light emitting element 14, such as a circle.

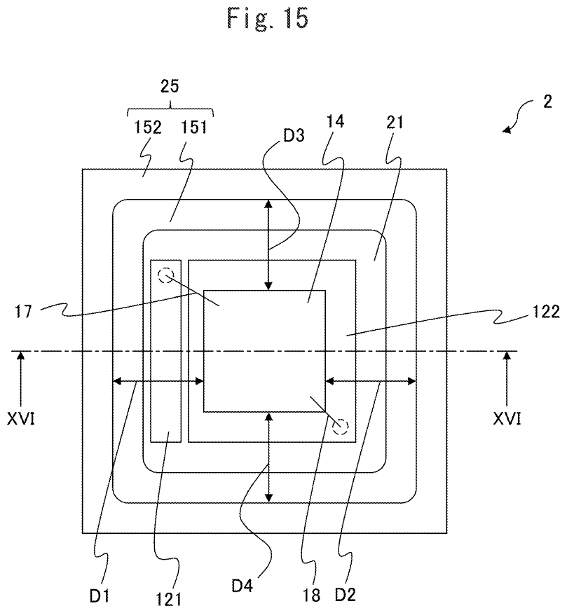

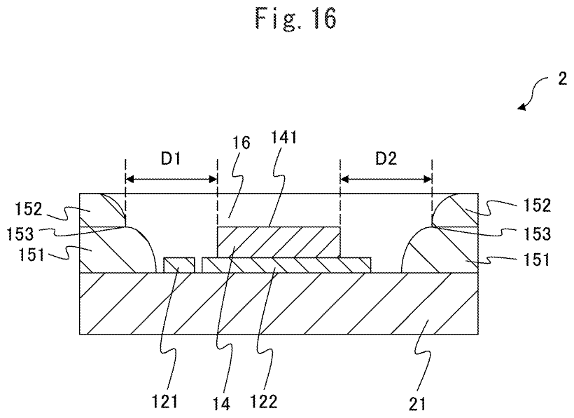

FIG. 15 is a plan diagram of a light emitting device 2 according to the second embodiment, and FIG. 16 is a cross-sectional diagram of the light emitting device 2. FIG. 16 is a cross-sectional diagram along a XVI-XVI line in FIG. 15. The light emitting device 2 differs from the light emitting device 1 in having a substrate 21 in place of the substrate 11 and a frame body 25 in place of the frame body 15. The same symbol is attached to the same configuration as that of the embodiment described above, and explanation is omitted appropriately.

The substrate 21 differs from the substrate 11 in being formed into the shape of substantially a square flat plate. The frame body 25 is arranged on the top surface of the substrate 21 along the outer circumference of the substrate 21. The inner circumference of the frame body also has the shape of substantially a square plane by arranging the frame body 25 along the outer circumference of the substrate 21.

The light emitting element 14 is arranged on the top surface of the second wiring 122 so as to be located in the center of the frame body 25. Distances D1 to D4 between the four lateral surfaces of the light emitting element 14 and the connection portion 153 of the frame body 25, which faces each lateral surface, are substantially equal to one another, by arranging the light emitting element 14 on the top surface of the second wiring 122 so as to be located in the center of the frame body 25. It is preferable for each of the distances D1 to D4 to be less than or equal to 300 μm and further preferable to be 200 μm or less. The amount of attenuation of the light emitted in each direction from the light emitting element 14 until it reaches the connection portion 153 becomes small, by setting the distances D1 to D4 to 200 μm or less, and therefore the intensity of the light emitted to the outside of the light emitting device 2 is high and the light emitting device 2 may further improve the light extraction efficiency.

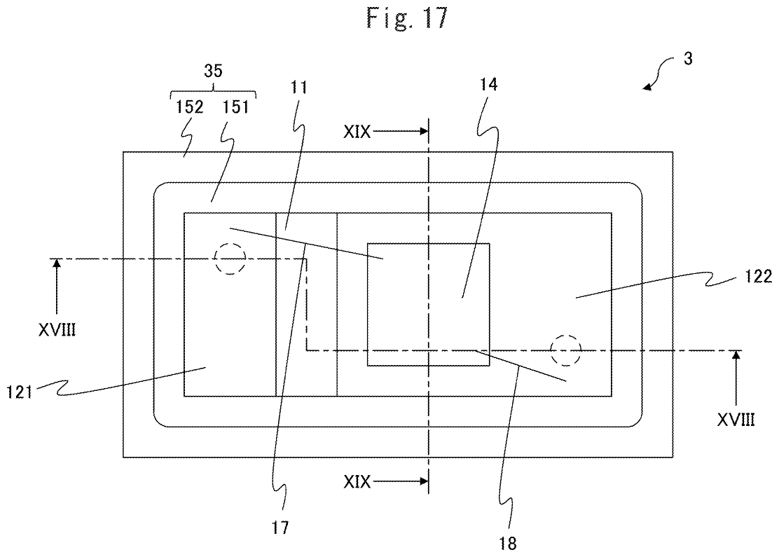

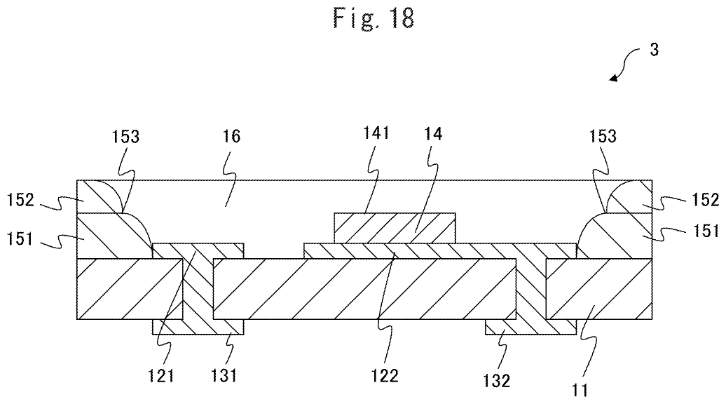

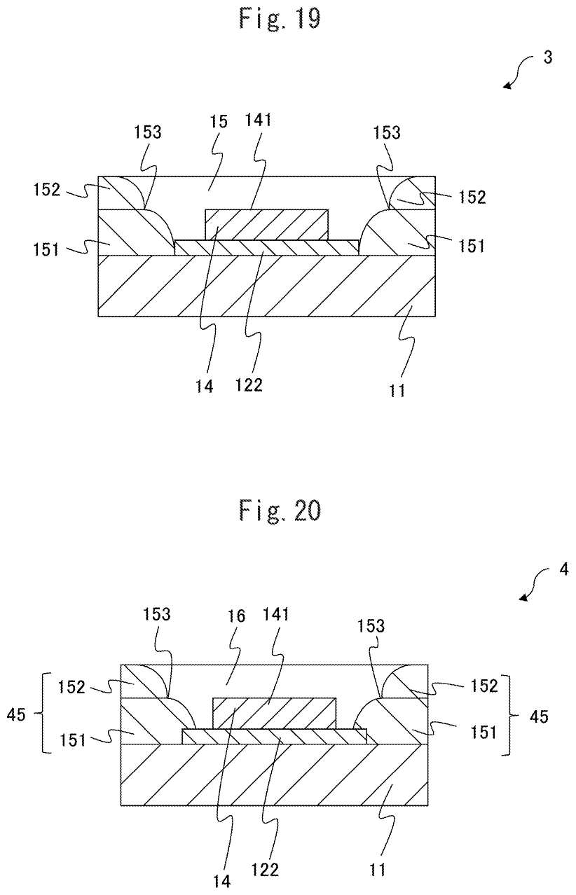

FIG. 17 is a plan diagram of a light emitting device 3 according to the third embodiment and FIG. 18 and FIG. 19 are each a cross-sectional diagram of the light emitting device 3. FIG. 18 is a cross-sectional diagram along an XVIII-XVIII line in FIG. 17 and FIG. 19 is a cross-sectional diagram along a XIX-XIX line in FIG. 17. The light emitting device 3 differs from the light emitting device 1 in having a frame body 35 in place of the frame body 15.

The frame body 35 differs from the frame body 15 in being arranged so that the inner circumference thereof contacts with the outer circumference of the first wiring 121 and the second wiring 122. Thus, the frame body 35 covers the whole area outside the wiring pattern 12 of the substrate 11. The area outside the wiring pattern 12 refers to the area outside the rectangle or the convex figure containing the first wiring 121 and the second wiring 122.

The substrate 11 is formed of insulating resin, and therefore, if the substrate 11 is irradiated with the light from the light emitting element 14 for a long time, the resin deteriorates (turns into soot) and the frame body may peel off from the substrate 11. On the other hand, the frame body 35 reflects the light from the light emitting element 14, and therefore such deterioration is unlikely to occur. In the substrate 11, since the whole area outside the first wiring 121 and the second wiring 122 is covered by the frame body 35, the deteriorating range of the substrate 11 is small, and therefore the light emitting device 3 may reduce the possibility that the frame body 35 peels off from the substrate 11.

Further, the frame body 35 contacts with the outer circumference of the first wiring 121 and the second wiring 122. Since the frame body 35 contacts with the outer circumference of the first wiring 121 and the second wiring 122, the distance from the light emitting element 14 to the connection portion 153 of the frame body 35 is reduced and the amount of attenuation of the light emitted laterally from the light emitting element 14 until it reaches the connection portion 153 is small, and therefore the light emitting device 3 may further improve the light extraction efficiency.

FIG. 20 is a cross-sectional diagram of a light emitting device 4 according to the fourth embodiment. FIG. 20 is a cross-sectional diagram at the same cross section as that in FIG. 19. The light emitting device 4 differs from the light emitting device 1 in having a frame body 45 in place of the frame body 15.

The frame body 45 differs from the frame body 15 in being arranged so as to cover the outer circumferential portion of the first wiring 121 and the second wiring 122. Thus, the frame body 45 further covers the outer circumferential portion of the first wiring 121 and the second wiring 122 as well as covering the whole area outside the first wiring 121 and the second wiring 122 of the substrate 11 like the frame body 35.

The first wiring 121 and the second wiring 122 are formed of silver and reflect the light from the light emitting element 14 and emit the light to the outside of the light emitting device 4. The sulfide gas has characteristics of penetrating resin, and therefore, when the light emitting device is used in an environment in which the sulfide gas exists, the sulfide gas penetrates the sealing material 16 made of resin and reacts with the first wiring 121 and the second wiring 122, causing the first wiring 121 and the second wiring 122 to deteriorate. When the first wiring 121 and the second wiring 122 deteriorate, the reflectance in the first wiring 121 and the second wiring 122 for the light from the light emitting element 14 may be reduced, and therefore the light extraction efficiency is reduced.

Since the frame body 45 covers the outer circumferential portion of the first wiring 121 and the second wiring 122 in the light emitting device 4, the light having reached the outer circumferential portion of the first wiring 121 and the second wiring 122 is reflected at the frame body 45 that is not affected by the sulfide gas. Since the light reached the outer circumferential portion of the first wiring 121 and the second wiring 122 is reflected at the frame body 45, the light emitting device 4 may suppress the degree of reduction in the light extraction efficiency, which is caused by the influence of the sulfide gas. It is preferable for the frame body 45 to be formed so as to cover the range of 100 μm from the outer circumference of the first wiring 121 and the second wiring 122, in order to suppress the degree of reduction in the light extraction efficiency.

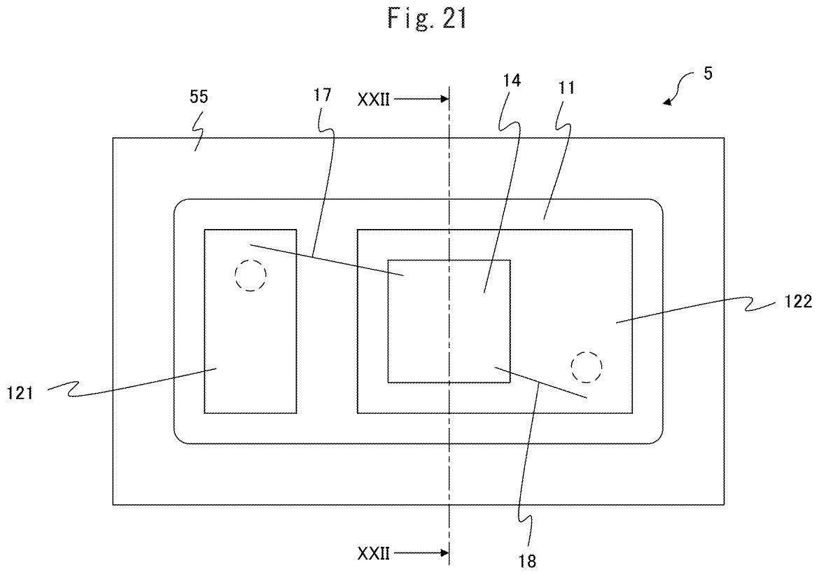

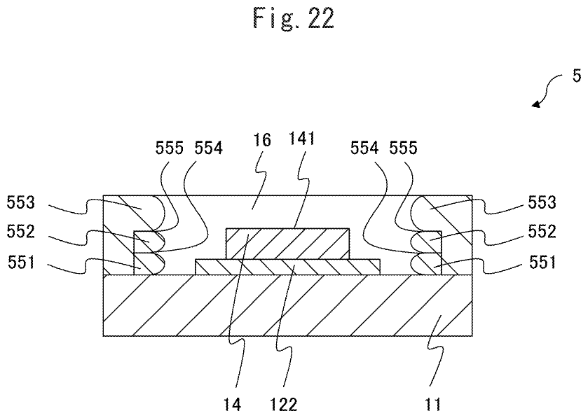

FIG. 21 is a plan diagram of a light emitting device 5 according to the fifth embodiment, and FIG. 22 is a cross-sectional diagram of the light emitting device 5. FIG. 22 is a cross-sectional diagram along a XXII-XXII line in FIG. 21. The light emitting device 5 differs from the light emitting device 1 in having a frame body 55 in place of the frame body 15.

The frame body 55 has a first frame portion 551, a second frame portion 552 connecting to the top portion of the first frame portion 551, and a third frame portion 553 connecting to the top portion of the second frame portion 552. The first frame portion 551 has a first inner circumferential curved surface protruding to the side of the light emitting element 14, the second frame portion 552 has a second inner circumferential curved surface protruding to the side of the light emitting element 14, and the third frame portion 553 has a third inner circumferential curved surface protruding to the side of the light emitting element 14. The third frame portion 553 is formed thicker than the first frame portion 551 and the second frame portion 552 and covers the outer circumferential surface of first frame portion 551 and the second frame portion 552 as well as covering the top surface of the second frame portion 552.

In a connection portion 554 between the first frame portion 551 and the second frame portion 552, the first frame portion 551 has the shape of a cross section convex upward and the second frame portion 552 has the shape of a cross section convex downward. Since the first frame portion 551 has the shape of a cross section convex upward and the second frame portion 552 has the shape of a cross section convex downward, the light radiated laterally from the light emitting element 14 is reflected upward at the connection portion 554, and therefore the light emitting device 5 may improve the light extraction efficiency.

Similarly, in a connection portion 555 between the second frame portion 552 and the third frame portion 553, the second frame portion 552 has the shape of a cross section convex upward and the third frame portion 553 has the shape of a cross section convex downward. Since the second frame portion 552 has the shape of a cross section convex upward and the third frame portion 553 has the shape of a cross section convex downward, the light radiated laterally from the light emitting element 14 is reflected upward at the connection portion 555, and therefore the light emitting device 5 may improve the light extraction efficiency.

Further, the connection portion 555 of the second frame portion 552 and the third frame portion 553 is located at the same height as that of the top surface 141 of the light emitting element 14. By causing the connection portion 555 to be located at the same height as that of the top surface 141 of the light emitting element 14, much of the light emitted laterally from the light emitting element 14 is emitted to the outside of the light emitting device 5 by one-time reflection, and therefore the light extraction efficiency further improves. It may also be possible for the connection portion 554 of the first frame portion 551 and the second frame portion 552 to be arranged at the same height as that of the top surface 141 of the light emitting element 14 in place of the connection portion 555.

In the connection portion 554 of the first frame portion 551 and the second frame portion 552, the first frame portion 551 and the second frame portion 552 may be formed into the shape of a plane. Thus, in the connection portion 554, a groove in the shape of a V-letter or in the shape of a saw tooth may be formed. In the case, the light radiated laterally from the light emitting element 14 is reflected upward at the connection portion 554, and therefore, the light emitting device 5 may improve the light extraction efficiency. Further, similarly, in the connection portion 555 of the second frame portion 552 and the third frame portion 553, a groove in the shape of a V-letter or in the shape of a saw tooth may be formed.

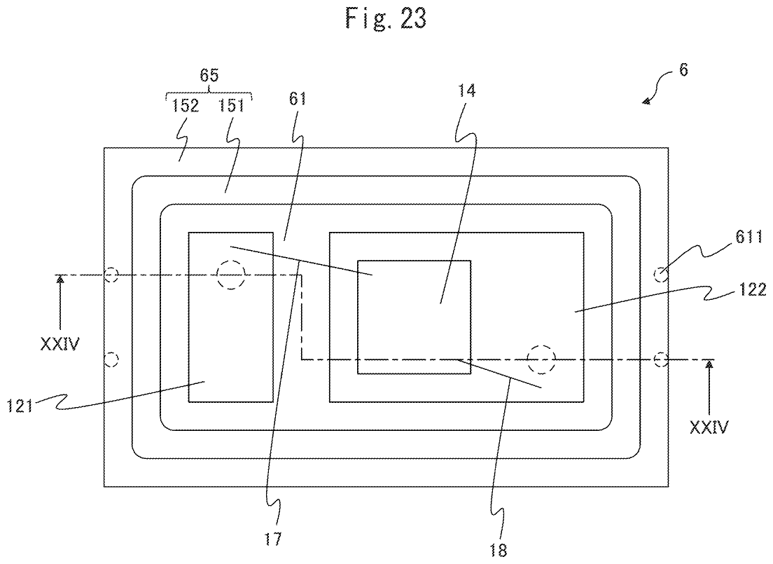

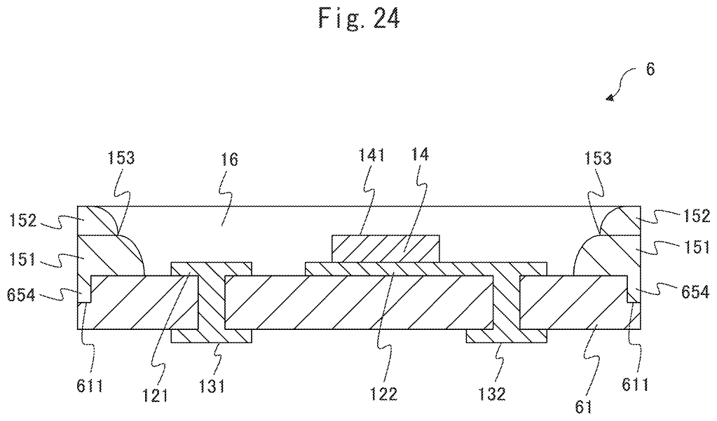

FIG. 23 is a plan diagram of a light emitting device 6 according to the sixth embodiment, and FIG. 24 is a cross-sectional diagram of the light emitting device 6. FIG. 24 is a cross-sectional diagram along a XXIV-XXIV line in FIG. 22. The light emitting device 6 differs from the light emitting device 1 in having a substrate 61 in place of the substrate 11 and having a frame body 65 in place of the frame body 15.

The substrate 61 differs from the substrate 11 in having a plurality of concave portions 611 (in FIG. 23, shown schematically by broken lines) in the outer circumferential portion of the top surface. The plurality of concave portions 611 is provided along a pair of sides facing each other of the rectangular substrate 61. The frame body 65 differs from the frame body 15 in having a plurality of convex portions 654 in the outer circumferential portion of the bottom surface. Each of the plurality of convex portions 654 is provided at the position and in the shape corresponding to the concave portion 611. The frame body 65 is fixed to the substrate 61 by the convex portion 654 fitting into the concave portion 611. Since the frame body 65 is fixed to the substrate 61, as described above, even if the resin forming the substrate 61 deteriorates (turns into soot), the possibility that the frame body 65 peels off from the substrate 61 is reduced.

Although, in the explanation described above, the concave portion 611 is provided along the pair of sides facing each other of the rectangular substrate 61, the provision of the concave portion 611 is not limited to the example, and the concave portion 611 may be provided along each side of the substrate 61, or may be provided along only one of the sides. Further, although, in the explanation described above, the plurality of concave portions 611 is provided along the side, the provision of the concave portion 611 is not limited to the example, and only the one concave portion 611 extending from one end to the other end of one side may be provided.

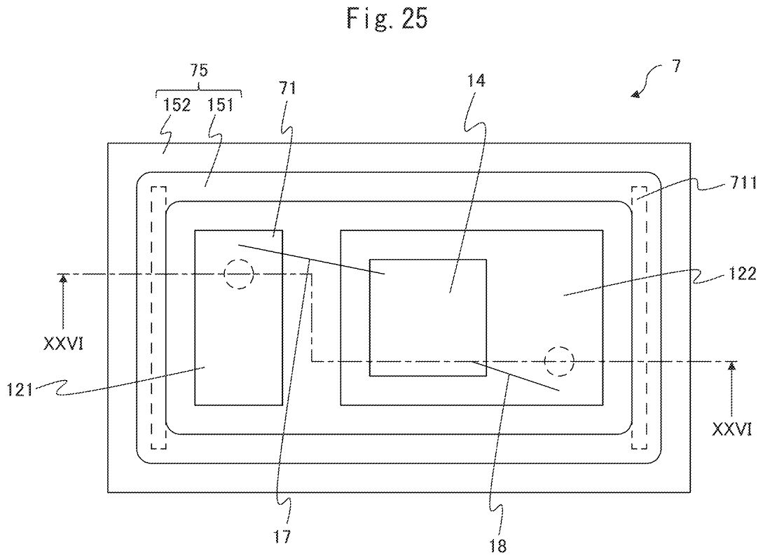

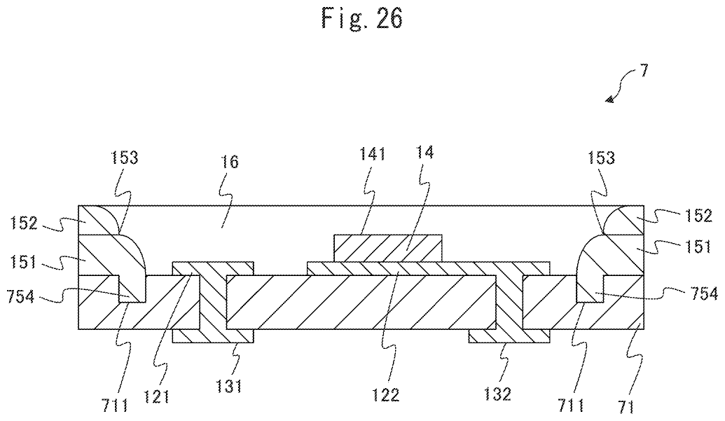

FIG. 25 is a plan diagram of a light emitting device 7 according to the seventh embodiment and FIG. 26 is a cross-sectional diagram of the light emitting device 7. FIG. 26 is a cross-sectional diagram along a XXVI-XXVI line in FIG. 25. The light emitting device 7 differs from the light emitting device 1 in having a substrate 71 in place of the substrate 11 and having a frame body 75 in place of the frame body 15.

The substrate 71 differs from the substrate 11 in having a plurality of concave portions 711 (in FIG. 25, schematically shown by rectangular broken lines) in the top surface. The plurality of concave portions 711 extends along a pair of sides facing each other of the rectangular substrate 71 and is provided along the inner circumference of the frame body 75. The frame body 75 differs from the frame body 15 in having a plurality of convex portions 754 in the inner circumferential portion of the bottom surface. Each of the plurality of convex portions 754 is provided at the position and in the shape corresponding to the concave portion 711. The frame body 75 is fixed to the substrate 71, since the convex portion 754 fits into the concave portion 711. Since the frame body 75 is fixed to the substrate 71 by the convex portion 754 fitting into the concave portion 711, similar to the light emitting device 6, even if the resin forming the substrate 71 deteriorates (turns into soot), the possibility that the frame body 75 peels off from the substrate 71 is reduced. Further, since the convex portion 754 is provided along the inner circumference of the frame body 75, the light emitted downward from the light emitting element 14 and transmitted through the substrate 71 is reflected at the convex portion 754, and therefore the light no longer leaks to the outside from the lateral surface of the light emitting device 7.

Although, in the explanation described above, the concave portion 711 is provided along a pair of sides facing each other of the rectangular substrate 71, the provision of the concave portion 711 is not limited to the example. and the concave portion 711 may be provided along each side of the substrate 71, or may be provided along only one of the sides. Further, although, in the explanation described above, the concave portion 711 extends along the side and is provided, the provision of the concave portion 711 is not limited to the example, and a plurality of the concave portions 711 may be provided along the side.

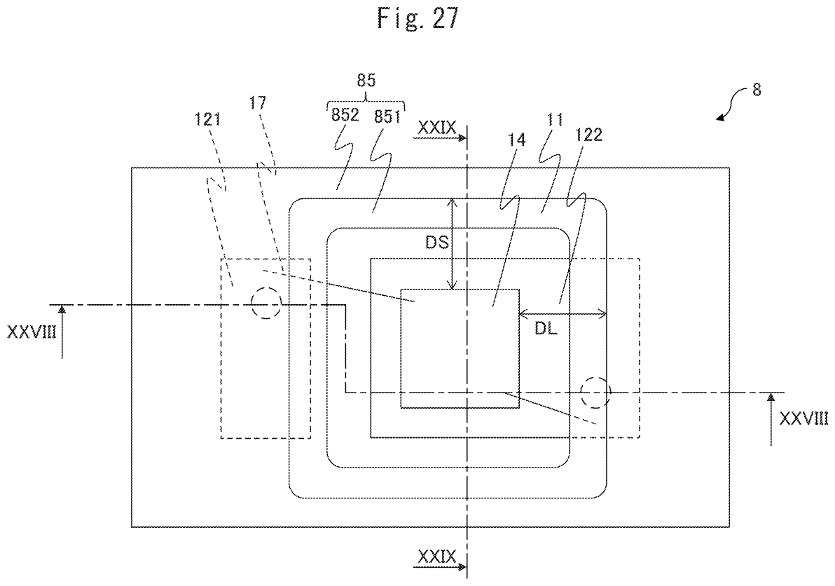

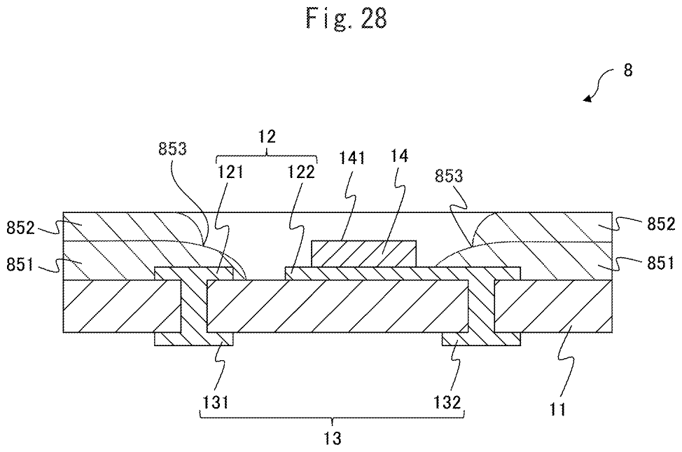

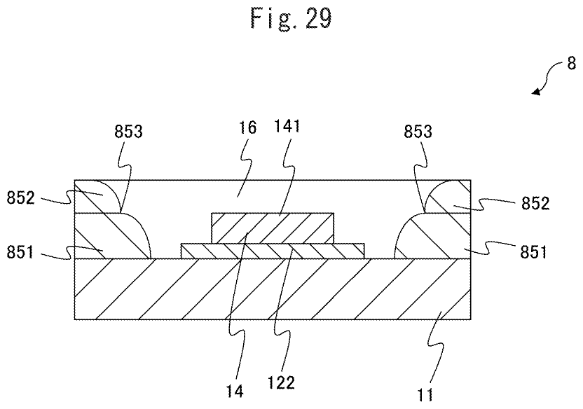

FIG. 27 is a plan diagram of a light emitting device 8 according to the eighth embodiment and FIG. 28 is a cross-sectional diagram (part 1) of the light emitting device 8 and FIG. 29 is a cross-sectional diagram (part 2) of the light emitting device 8. FIG. 28 is a cross-sectional diagram along a XXVIII-XXVIII line in FIG. 27 and FIG. 29 is a cross-sectional diagram along a XXIX-XXIX line in FIG. 27. The light emitting device 8 differs from the light emitting device 1 in having a frame body 85 in place of the frame body 15.

The frame body 85 has a first frame portion 851 having a first inner circumferential curved surface protruding to the side of the light emitting element 14 and a second frame portion 852 connecting to the top portion of the first frame portion 851 and having a second inner circumferential curved surface protruding to the side of the light emitting element 14. Similar to the frame body 15, the frame body 85 has the shape in which the second frame portion 852 is stacked on the first frame portion 851. A connection portion 853 between the first frame portion 851 and the second frame portion 852 is arranged so as to have the same height as that of the top surface 141 of the light emitting element 14. The first inner circumferential curved surface and the second inner circumferential curved surface each have the shape of a cross section convex upward.

The first frame portion 851 and the second frame portion 852 are formed so that the width of the portion arranged at both ends in the long-side direction of the substrate 11 is greater than the width of the portion arranged at both ends in the short-side direction of the substrate 11. The width of the first frame portion 851 and the second frame portion 852 at both ends in the long-side direction of the substrate 11 is greater than the width at both ends in the short-side direction of the substrate 11, and therefore the width of the frame body 85 arranged at both ends in the long-side direction of the substrate 11 is greater than the width of the frame body 85 arranged at both ends in the short-side direction of the substrate 11.

A distance DL between the top end of the opposing second inner circumferential curved surfaces of the second frame portion 852 arranged in the long-side direction and the light emitting element 14 is the same as a distance DS between the top end of the opposing second inner circumferential curved surfaces of the second frame portion 852 arranged in the short-side direction and the light emitting element 14. When the distance between the distance DL and the distance DS is less than or equal to ±10% of the distance DL, the distance DL and the distance DS are regarded as the same. The distance DL and the distance DS are the same, and therefore the shape of the top surface of the sealing material 16 in a plan view is a square, which is arranged so that the end portion thereof contacts with the top end of the second inner circumferential curved surface of the second frame portion 852. The shape of the top surface of the sealing material 16, i.e., the planar shape of the light emitting surface of the light emitting device 8 is a square.

Since the light emitting surface of the light emitting device 8 has the shape of a square plane, the light emitting device 8 may function as a point light source having the same directivity both in the long-side direction and in the short-side direction of the rectangular substrate 11 having the side extending in the long-side direction and the side extending in the short-side direction. The frame body 85 protects the joint portion joining the first wiring 121 and the bonding wire 17 and the joint portion joining the second wiring 122 and the bonding wire 18 by covering them. Further, the frame body 85 is arranged so as to cover the first wiring 121 and the second wiring 122 arranged above the through hole. the first wiring 121 and the second wiring 122 arranged above the through hole may have the shape of a concave more concave than the other portions of the first wiring 121 and the second wiring 122. In the light emitting device 8, the frame body 85 is arranged so as to cover the concave portion of the first wiring 121 and the second wiring 122 arranged above the through hole, and therefore the fluorescent substance is prevented from precipitating in the concave portion formed in the first wiring 121 and the second wiring 122. In the light emitting device 8, the fluorescent substance dose not precipitate in the concave portion formed in the first wiring 121 and the second wiring 122, and therefore color unevenness may be prevented from occurring, which is caused by the yellow light being emitted from the fluorescent substance having precipitated in the concave portion. Further, in the light emitting device 8, the frame body 85 is arranged so as to cover the concave portion formed in the first wiring 121 and the second wiring 122, and therefore the possibility that the optical characteristics are reduced even if air bubbles occur in the concave portion.

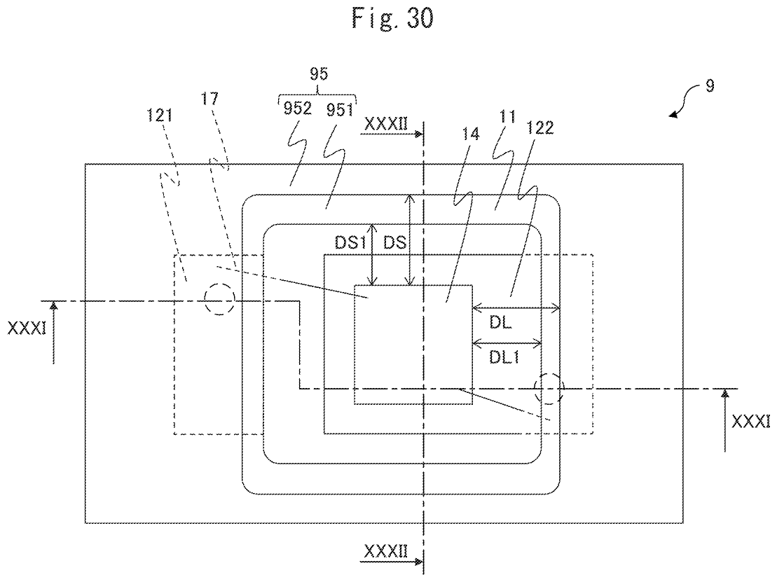

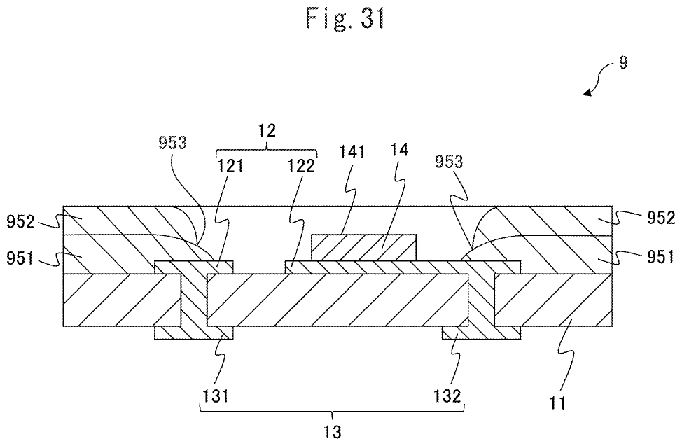

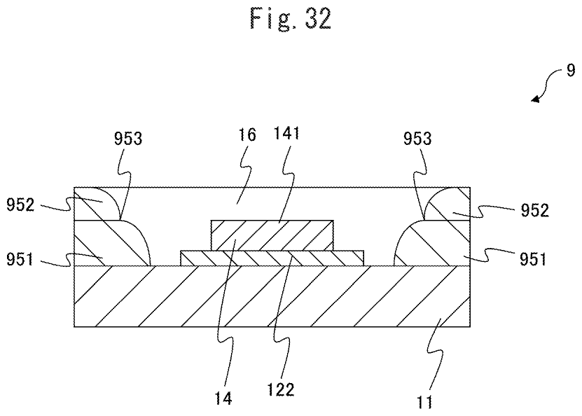

FIG. 30 is a plan diagram of a light emitting device 9 according to the ninth embodiment and FIG. 31 is a cross-sectional diagram (part 1) of the light emitting device 9 and FIG. 32 is a cross-sectional diagram (part 2) of the light emitting device 9. FIG. 31 is a cross-sectional diagram along a XXXI-XXXI line in FIG. 30 and FIG. 32 is a cross-sectional diagram along a XXXII-XXXII line in FIG. 30. The light emitting device 9 differs from the light emitting device 8 in having a frame body 95 in place of the frame body 85.

The frame body 95 has a first frame portion 951 having a first inner circumferential curved surface protruding to the side of the light emitting element 14 and a second frame portion 952 connecting to the top portion of the first frame portion 951 and having a second inner circumferential curved surface protruding to the side of the light emitting element 14. Similar to the frame body 85, the frame body 95 has the shape in which the second frame portion 952 is stacked on the first frame portion 951. A connection portion 953 between the first frame portion 951 and the second frame portion 952 is arranged so as to have the same height as that of the top surface 141 of the light emitting element 14. The first inner circumferential curved surface and the second inner circumferential curved surface each have the shape of a cross section convex upward.

The first frame portion 951 and the second frame portion 952 are formed so that the width of the portion arranged at both ends in the long-side direction of the substrate 11 is greater than the width of the portion arranged at both ends in the short-side direction of the substrate 11 similar to the first frame portion 851 and the second frame portion 852. The width of the first frame portion 951 and the second frame portion 952 at both ends in the long-side direction of the substrate 11 is greater than the width at both ends in the short-side direction of the substrate 11, and therefore, the width of the frame body 95 arranged at both ends in the long-side direction of the substrate 11 is greater than the width of the frame body 95 arranged at both ends in the short-side direction of the substrate 11.

A distance DL between the top end of the opposing second inner circumferential curved surfaces of the second frame portion 952 arranged in the long-side direction and the light emitting element 14 is the same as a distance DS between the top end of the opposing second inner circumferential curved surfaces of the second frame portion 952 arranged in the short-side direction and the light emitting element 14, similar to the first frame portion 851 and the second frame portion 852. The distance DL and the distance DS are the same, and therefore the shape of the top surface of the sealing material 16 in a plan view is a square, which is arranged so that the end portion thereof contacts with the top end of the second inner circumferential curved surface of the second frame portion 952. The shape of the top surface of the sealing material 16, i.e., the planar shape of the light emitting surface of the light emitting device 8 is a square like the planar shape of the light emitting surface of the light emitting device 8.

However, a separation distance DL1 between the front end of the first frame portion 951 arranged in the long-side direction and the light emitting element 14 is longer than a separation distance DS1 between the front end of the first frame portion 951 arranged in the short-side direction and the light emitting element 14. The first frame portion 951 arranged in the short-side direction has a comparatively short distance between the end portion of the substrate 11 and the light emitting element 14 and the surface of the substrate 11 is flat, and therefore it is easy to control the separation distance between the front end of the first frame portion 951 and the light emitting element 14. On the other hand, the first frame portion 951 arranged in the long-side direction has a comparatively long distance between the end portion of the substrate 11 and the light emitting element 14 and the surface of the substrate 11 is formed with concavities and convexities, and therefore it is not easy to control the separation distance between the front end of the first frame portion 951 and the light emitting element 14.

In the light emitting device 9, since the first frame portion 951 arranged in the long-side direction is arranged more distant from the light emitting element 14 than from the first frame portion 951 arranged in the short-side direction, the light emission efficiency of the light emitting device 9 may be reduced, since the first frame portion 951 comes into contact with the light emitting element 14.

Further, in the light emitting device 9, since the first frame portion 951 arranged in the long-side direction is arranged more distant from the light emitting element 14 than from the first frame portion 951 arranged in the short-side direction, the directivity in the long-side direction may differ from the directivity in the short-side direction.

Although, in the light emitting device 9, the first frame portion 951 arranged in the long-side direction is arranged more distant from the light emitting element 14 than from the first frame portion 951 arranged in the short-side direction, in the light emitting device according to the embodiment, the first frame portion may be arranged so that the separation distances between the four sides of the light emitting element and the first frame portion are different from one another. Since the first frame portion is arranged so that the separation distances between the four sides of the light emitting element and the first frame portion are different from one another, the peak position of the directivity of emitted light may be changed from the top of the light emitting element 14.

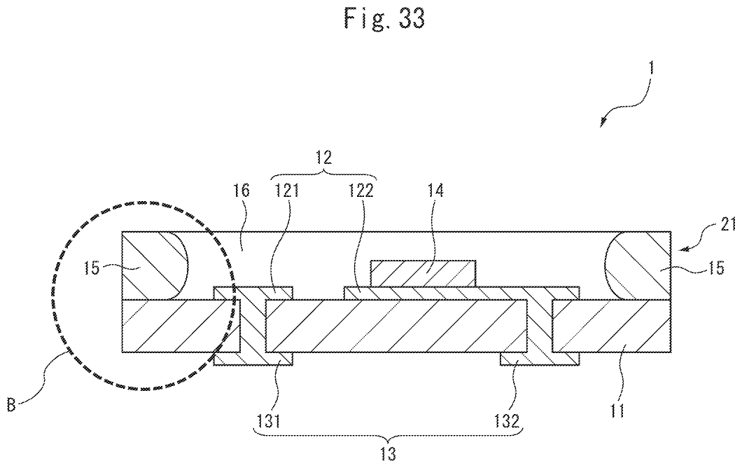

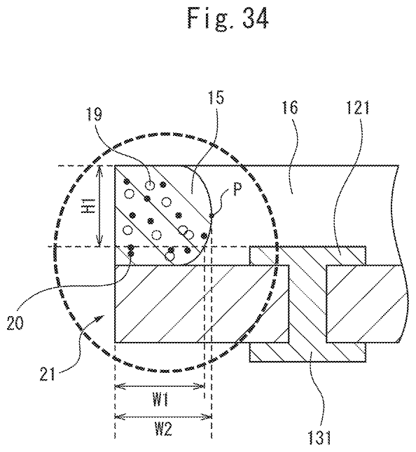

FIG. 33 is a cross-sectional diagram of a light emitting device 10 according to the tenth embodiment, and FIG. 34 is a partially enlarged cross-sectional diagram of the portion surrounded by a broken line A shown in FIG. 33. FIG. 33 is a cross-sectional diagram corresponding to FIG. 2. The light emitting device 10 differs from the light emitting device 1 in having a frame body 15a comprising a first frame body 151a and a second frame body 152a in place of the frame body 15.

The frame body 15a is arranged in the shape of a rectangle along the outer circumference of the substrate 11 on the top surface of the substrate 11 so as to surround the LED element 14, the first wiring 121, and the second wiring 122. The frame body 15a is a white resin formed by dispersing fine particles of titanium oxide (TiO₂) in a base resin, such as a silicon resin or an epoxy resin, and has a function to reflect the light from the LED element 14. Further, the frame body 15a includes first particle diameter fillers 19 and second particle diameter fillers 20 as shown in FIG. 34. Furthermore, as will be described later, the left and right lateral surfaces of the frame body 15a are each a diced lateral surface 10a. The frame body 15a may not necessarily include the fine particles of titanium oxide (TiO₂).

The surface of the first wiring 121 and the second wiring 122 may be irradiated with plasma and etc., to turn the surface into a rough surface. When the surface of the first wiring 121 and the second wiring 122 is turned into a rough surface, the frame body 15a may be suppressed from climbing up the surface of the first wiring 121 and the second wiring 122 unintendedly.

The first particle diameter fillers 19 are inorganic particles, such as silicon dioxide, iron oxide, and aluminum oxide, and the average particle diameter thereof is 1 to 100 μm. The hardened frame body 15a in the completed light emitting device 10 contains the first particle diameter fillers 19 of 10 to 50 wt % with respect to the base resin. When the first particle diameter fillers 19 are contained in the frame body, the hardness of the hardened frame body 15a is high. When the frame body includes only the first particle diameter fillers 19 of less than 10 wt %, the hardness of the frame body is not sufficient and it is difficult to keep the outer appearance of a product in a good state, because burrs, etc. occur at the time of cutting, such as dicing. On the other hand, when the frame body includes the first particle diameter fillers 19 of more than 50 wt %, it is difficult to maintain the shape of the frame body in a predetermined shape because of the bearing effect of the particles. Thus, in the light emitting device 10, the hardened frame body 15a in the completed light emitting device 10 is caused to contain the first particle diameter fillers 19 of 10 to 50 wt % with respect to the base resin, in order to have a good-state dicing lateral surface. The details thereof will be described later.

The second particle diameter fillers 20 are inorganic particles, such as silica, silicon dioxide, iron oxide, and aluminum oxide, and the average particle diameter thereof is 1 to 500 nm. The hardened frame body 15a in the completed light emitting device 10 contains the second particle diameter fillers 20 of 4 to 15 wt % with respect to the base resin. When the frame body 15a contains the second particle diameter fillers 20, the viscosity becomes high at the time of manufacture, and therefore the viscosity between particles can be maintained high and the shape may be kept high in the height direction and small in the width direction. When the frame body 15a includes only the second particle diameter fillers 20 of less than 4 wt %, the viscosity of the frame body before hardening is not high enough, and therefore it is difficult to maintain a desired shape. On the other hand, when the frame body includes the second particle diameter fillers 20 of more than 15 wt %, the viscosity is too high, and therefore clogging occurs in the application nozzles, and it is difficult to apply a resin for forming the frame body. Thus, in the light emitting device 10, the hardened frame body 15a in the completed light emitting device 10 is caused to contain the second particle diameter fillers 20 of 4 to 15 wt % with respect to the base resin, in order to form a frame body having a desired shape. The details thereof will be described later. It is preferable for the second particle diameter fillers 20 to have a specific surface area of 50 to 500 m²/g.

The average particle diameter of the first particle diameter fillers 19 and the second particle diameter fillers 20 described above is measured by the following method. For the first diameter filler particles 19, first, the frame body 15a is cut and the cut surface is observed by an electron microscope. At the time, the fifty first diameter filler particles are specified in the range of 500 μm² and the average value of the long diameters of the first diameter filler particles is taken as the average particle diameter. Similarly, for the second diameter filler particles 20, first, the frame body 15a is cut and the cut surface is observed by the electron microscope. At the time, the fifty second diameter filler particles are specified in the range of 100 μm² and the average value of the long diameters of the second diameter filler particles is taken as the average particle diameter.

In the manufacturing method of the light emitting device 10, the resin droplets prepared in the frame body arrangement process shown at S103 in FIG. 12 are different. In the manufacturing method of the light emitting device 10, in place of the white resin droplets containing titanium oxide, white resin droplets are prepared in which fine particles of titanium oxide, the first particle diameter filler particles 19, and the second particle diameter filler particles 20 are dispersed in a thermosetting base resin, such as a silicon resin. The manufacturing method of the light emitting device 10 is the same as the manufacturing method of the light emitting device 1 except for the resin droplets prepared in the frame body arrangement process shown at S103 in FIG. 12, and therefore a detailed explanation is omitted here.

The top surface of the second frame portion 152a may be formed flat by pressing the top surface of the second frame portion 152a while the second frame portion 152a is hardening or after the second frame portion 152a hardens. When the top surface of the second frame portion 152a is formed flat, even if the cutting position at which dicing is performed for individuation shifts somewhat, the height of the cut second frame portion 152a is not affected, and therefore the light emitting device 10 of uniform quality is manufactured. The shape of the curve of the inner circumferential surface of the first frame portion 151a and the second frame portion 152a may be adjusted by pressing. For example, the center of the curve moves in the direction toward the vertex of the dam from the substrate surface by pressing strongly, and the width of the frame body in the range of the lateral side and the height of the LED element 14 increases, and therefore light does not leak from the lateral side.

As described above, the height of the product may be adjusted, by adopting the structure in which a plurality of frame portions is stacked in the frame body 15a. The width of the bottom surface of the second frame portion 152a is the same as the width of the flat portion of the top surface of the first frame portion 151a. Since the aspect ratio of the width of the bottom surface to the height of the first frame portion 151a is the same as that of the second frame portion 152a, the height of the dam of the second frame portion 152a may be controlled by the width of the flat portion of the top surface of the first frame portion 151a. The total of the heights of the first frame portion 151a and the second frame portion 152a may be the same as the height of the frame body 15. Further, the width of the first frame portion 151a may be the same as the width of the frame body 15a.

It is preferable for an inclination angle (0) formed by the tangential plane tangent to the inner circumferential curved surface of the first frame portion 151a and the inner circumferential curved surface of the second frame portion 152a and the substrate 11 to be not less than 65 degrees and not more than 75 degrees, and further preferable to be not less than 70 degrees and not more than 75 degrees. Much of the light emitted in the horizontal direction from the LED element 14 is reflected vertically upward at the frame body 15a, by setting the inclination angle (0) of the tangential plane not less than 65 degrees and not more than 75 degrees, and therefore the light extraction efficiency of the light emitting device 10 improves and at the same time, the spread of the light flux emitted to the outside from the light emitting device 10 is suppressed.

Further, much of the light emitted in the horizontal direction from the LED element 14 is reflected vertically upward at the frame body 15a, by setting the inclination angle (0) of the tangential plane not less than 65 degrees and not more than 75 degrees, and therefore the light extraction efficiency of the light emitting device 10 improves and at the same time, the spread of the light flux emitted to the outside from the light emitting device 10 is suppressed, and therefore the optical characteristics of the light emitting device 10 improve.

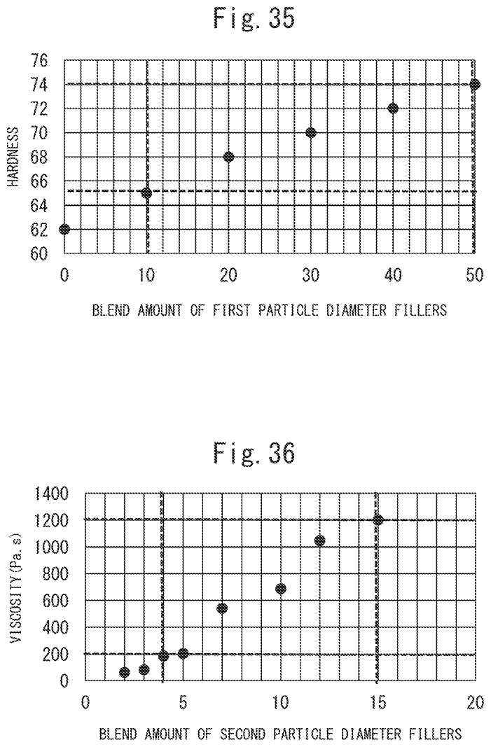

FIG. 35 is a diagram showing a relationship between the blend amount of the first particle diameter fillers 19 in the frame body 15a and the hardness of the frame body 15a. The blend amount indicates the mass ratio (wt %) of the first particle diameter fillers 19 with respect to the base resin in the hardened frame body 15a in the completed light emitting device 10. The hardness indicates the Shore D hardness. FIG. 35 is results of measuring the Shore D hardness of the frame body 15a by changing the blend amount of the first particle diameter fillers 19 included in the frame body 15a.

As shown in FIG. 35, if the frame body is caused to contain the first particle diameter fillers 19, the hardness of the hardened frame body 15a is high. In general, when the Shore D hardness is 65 or more, the burrs and chip conspicuous in the outer appearance at the time of cutting, such as dicing, do not occur, and therefore the light emitting device having a good outer appearance may be manufactured. Further, if the frame body 15a is caused to contain the first particle diameter fillers 19, the viscosity of the frame body 15a may be reduced and when the Shore D hardness is higher than 74, it is difficult to maintain the shape of the frame body in a predetermined shape because of the bearing effect of particles. In the hardened frame body 15a in the completed light emitting device 10, the preferable range of the mass ratio (wt %) of the first particle diameter fillers 19 with respect to the base resin is taken to be 10 to 50 wt %. When the content of the first particle diameter fillers 19 is increased and the Shore D hardness becomes higher than 74, clogging occurs in the application nozzles, and therefore it is difficult to apply a resin for forming the frame body.

FIG. 36 is a diagram showing a relationship between the blend amount of the second particle diameter fillers 20 and viscosity in the frame body 15a. The blend amount indicates the mass ratio (wt %) of the second particle diameter fillers 20 with respect to the base resin in the hardened frame body 15a in the completed light emitting device 10. The viscosity indicates the viscosity (Pa S) of the white resin droplets before hardening. FIG. 36 is results of measuring the viscosity by changing the blend amount of the second particle diameter fillers 20 included in the white resin droplets before hardening, which is created for the frame body 15a.

As shown in FIG. 36, if the second particle diameter fillers 20 are contained in the white resin droplets before hardening, the viscosity is high. In general, when the viscosity is 200 (Pa·S) or higher, the viscosity is high during manufacturing process, and may maintain high viscosity between particles and keep the shape high in the height direction and small in the width direction. Further, when the viscosity is higher than 1,200 (Pa·S), the viscosity is too high and clogging occurs in the application nozzles, and therefore it is difficult to apply a resin for forming the frame body. In the hardened frame body 15a in the completed light emitting device 10, the preferable range of the mass ratio (wt %) of the second particle diameter fillers 20 with respect to the base resin is set to 4 to 15 wt %. The mass ratio (wt %) of the second particle diameter fillers 20 in FIG. 36 is calculated by taking into consideration that the mass of the frame body 15a decreases by 0 to 10% after hardening.

When the viscosity of the white resin droplets before hardening for forming the frame body 15a is low, the aspect ratio of the width of the bottom surface to the height of the frame body 15a may be maintained at a high level, and therefore the dam shape is a sagged shape. The frame body 15a contacts with the LED element 14 and light emission efficiency is reduced, and therefore it is difficult to obtain a compact light emitting device.

Further, it is preferable for the ratio of the width of the bottom surface (width from the position of the frame body 15a parallel to the top surface of the first wiring 121 to a lateral surface 21: W3) to a height (H2) of the first frame portion 151a from the electrode 121 in the light emitting device 10 (see FIG. 33) to be 1.2 to 2.0, and in that case, the shape is suitable for the formation of the second frame portion 152a.

As described previously, the frame body 15a has titanium oxide and it is preferable for the mass ratio (wt %) of the titanium oxide to the base resin to be in the range between 10 and 70 wt % with respect to the base resin and in that case, the frame body 15a reflects light well. As described previously, it is preferable for the ratio of the width of the bottom surface (W1) to the height (H1) of the frame body 15a to be 0.6 to 4.0, but in that case, the width of the frame body 15a may be reduced, and therefore the titanium oxide whose mass ratio is higher than usual is necessary. In the frame body 15a, if the mass ratio (wt %) of the titanium oxide to the base resin is 10 to 70 wt %, even when the width of the frame body 15a is, for example, less than or equal to 0.1 mm, the light from the LED element 14 does not penetrate the frame body 15a, and therefore the frame body 15a may reflect light efficiently.

As described previously, the frame body 15a may not contain titanium oxide. In other words, the frame body 15a may be transparent. When the frame body 15a is formed transparent, the directivity of light may be extended. Further, the frame body 15a may be black or blue. When the frame body 15a is formed black, the occurrence of a yellow ring may be suppressed. Further, the frame body 15a may include a fluorescent substance. When the frame body 15a includes a fluorescent substance, the color temperature and the directivity of chromaticity may be adjusted. Only one of the first frame portion 151a and the second frame portion 152a of the frame body 15a may be transparent, black, or blue or may include a fluorescent substance.

In each side of the light emitting device 10, the structure of the first frame portion 151a alone and the structure of the first frame portion 151a and the second frame portion 152a may be combined. The one-stage frame portion is arranged at the short side after arranging the two-stage frame portion at the long side of the light emitting device 10. When the pitch at the center of the frame portion arranged on the side of the long side is 1.5 mm or less, since the frame body arranged on the two-stage dam comes into between the two-stage dam, the one-stage dam arranged on the side of the short side has the same height as that of the two-stage dam even, and therefore the number of processes may be reduced. The connection portion of the wire and the wiring may be protected and the directivity may be narrowed at the long side, by arranging the dams side by side on the side of the short side in place of stacking the dams one on top of another.

The size of R of four corners of the frame body 15a in a plan view of the light emitting device 10 may be changed. For example, when R of two adjacent angles is made larger than R of the other two corners, the adjacent angles may be used as a mark for recognizing the direction.

Further, in the light emitting device 10, the corner having large R may be changed between the first frame portion 151a and the second frame portion 152a. The recognition mark may be easier to see.

In the light emitting device 10, when the fluorescent substance contained in the sealing material 16 is caused to precipitate, the fluorescent substance may be deposited on the top portion of the first frame portion 151a and at the border with the second frame portion 152a. When the fluorescent substance is caused to precipitate, the lateral surface of the light emitting element 14 may be exposed from the precipitation layer of the fluorescent substance. In the case, since the blue light traveling laterally is strong, yellow light by the fluorescent substance compensates at the border between the first frame portion 151a and the second frame portion 152a, so that the blue light may be reduced traveling laterally.

The light emitting devices 1 to 9 have the frame body not containing the first particle diameter fillers 19 and the second particle diameter fillers 20. However, the light emitting devices 1 to 9 may have the frame body 15a containing the first particle diameter fillers 19 and the second particle diameter fillers 20 in place of the frame body not containing the first particle diameter fillers 19 and the second particle diameter fillers 20.

Further, in the light emitting device according to the embodiment, it is preferable for the separation distance between the end portion of the substrate and the front end of the first frame portion to be longer than the separation distance between the front end of the first frame portion and the end portion of the light emitting element in the short-side direction. In the light emitting device according to the embodiment, it is further preferable for the length obtained by adding the separation distance between the front end of one of the pair of the first frame portions facing each other and the end portion of the substrate and the separation distance between the front end of other of the pair and the end portion of the substrate to be longer than the length obtained by adding the separation distance between the front end of one of the pair of the first frame portions facing each other and the end portion of the light emitting element and the separation distance between the front end of the other of the pair and the end portion of the light emitting element in the short-side direction. Further, in the light emitting device according to the embodiment, it is preferable for the separation distance between the end portion of the substrate and the front end of the first frame portion to be twice or less the separation distance between the end portion of the substrate and the front end of the second frame portion in the short-side direction.

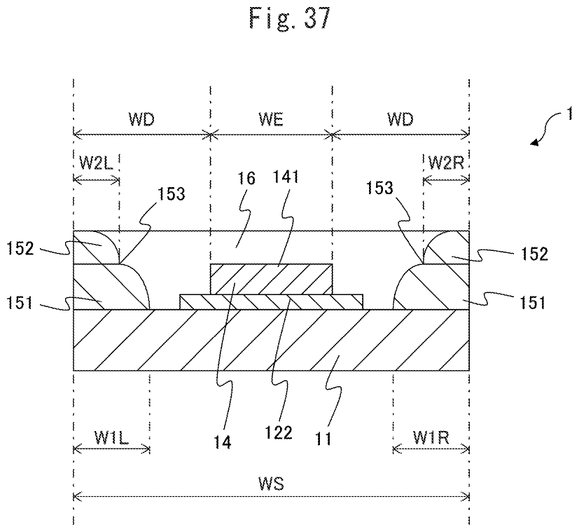

FIG. 37 is a diagram for explaining preferable arrangement in the short-side direction in the light emitting device according to the embodiment. FIG. 37 is a cross-sectional diagram corresponding to FIG. 3.

In the light emitting device according to the embodiment, it is preferable for a separation distance W1L between the end portion of the substrate 11 and the front end of the first frame portion 151 to be longer than a separation distance (WD−W1L) between the front end of the first frame portion 151 and the end portion of the light emitting element 14. Further, in the light emitting device according to the embodiment, it is preferable for a separation distance W1R between the end portion of the substrate 11 and the front end of the first frame portion 151 to be longer than a separation distance (WD−W1R) between the front end of the first frame portion 151 and the end portion of the light emitting element 14.

In the light emitting device according to the embodiment, it is further preferable for the length obtained by adding the separation distance between the front end of one of the pair of the first frame portions 151 facing each other and the end portion of the substrate 11 and the separation distance between the front end of other of the pair and the end portion of the substrate 11 to be longer than the length obtained by adding the separation distance between the front end of one of the pair of the first frame portions 151 facing each other and the end portion of the light emitting element 14 and the separation distance between the front end of the other of the pair and the end portion of the light emitting element 14. The length obtained by adding the separation distance between the front end of one of the pair of the first frame portions 151 and the end portion of the substrate 11 and the separation distance between the front end of the other of the pair and the end portion of the substrate 11 is expressed by (WIL+W1R) and the length obtained by adding the separation distance between the front end of one of the pair of the first frame portions 151 and the end portion of the light emitting element 14 and the separation distance between the front end of the other of the pair and the end portion of the light emitting element 14 is expressed by (2×WD−(W1L+W1)), and therefore, the following relationship holds.

(WIL+W1R)≥(2×WD−(W1L+W1)) (1)

(2×WD) on the left side of formula (1) is expressed by (WS−WD), here, WS expresses the length in the short-side direction of the substrate 11 and WE expresses the width of the light emitting element 14, and therefore, formula (1) is rewritten as

(W1L+W1R)≥((WS−WD)−(W1L+W1R)) (2),

and therefore, the length (WS) in the short-side direction of the substrate 11, the width (WE) of the light emitting element 14, and the length (W1L+W1R) obtained by adding the separation distance between the front end of one of the pair of the first frame portions 151 and the end portion of the substrate 11 and the separation distance between the front end of the other of the pair and the end portion of the substrate 11 have the following relationship.

2≥(WS−WD)/(W1L+W1R)

In the light emitting device according to the embodiment, it is preferable for the separation distance W1L between the end portion of the substrate 11 and the front end of the first frame portion 151 to be twice or less a separation distance W2L between the end portion of the substrate 11 and the front end of the second frame portion 152 in the short-side direction. Further, in the light emitting device according to the embodiment, it is preferable for the separation distance W1R between the end portion of the substrate 11 and the front end of the first frame portion 151 to be twice or less a separation distance W2R between the end portion of the substrate 11 and the front end of the second frame portion 152 in the short-side direction. For example, when the width (WE) of the light emitting element 14 is twice or more the length (WS) in the short-side direction of the substrate 11, WS≤2×WE, i.e., when WD is small, at both ends of the light emitting element 14, the light traveling laterally from the light emitting element 14 is suppressed from being transmitted from the first frame portion 151, and therefore, it is possible to narrow the directivity of light as well as maintaining the amount of emitted light of the light emitting device 1.

### Embodiment 1

The change in directivity when the separation distance between the front end of the first frame portion 851 and the end portion of the light emitting element 14 is changed was observed by simulation, by using the light emitting device 8 whose planar shape of the light emitting surface is a square. The length of one side of the substrate 10 is 2.4 mm, the height of the first frame portion 851 is 268 μm, and the height of the second frame portion 852 is 222 μm. The height of the light emitting element 14 is 200 μm and the length of one side of the light emitting surface of the emitting element 14 is 650 μm. The radiant intensity of the light emitting element 14 is 1 W.

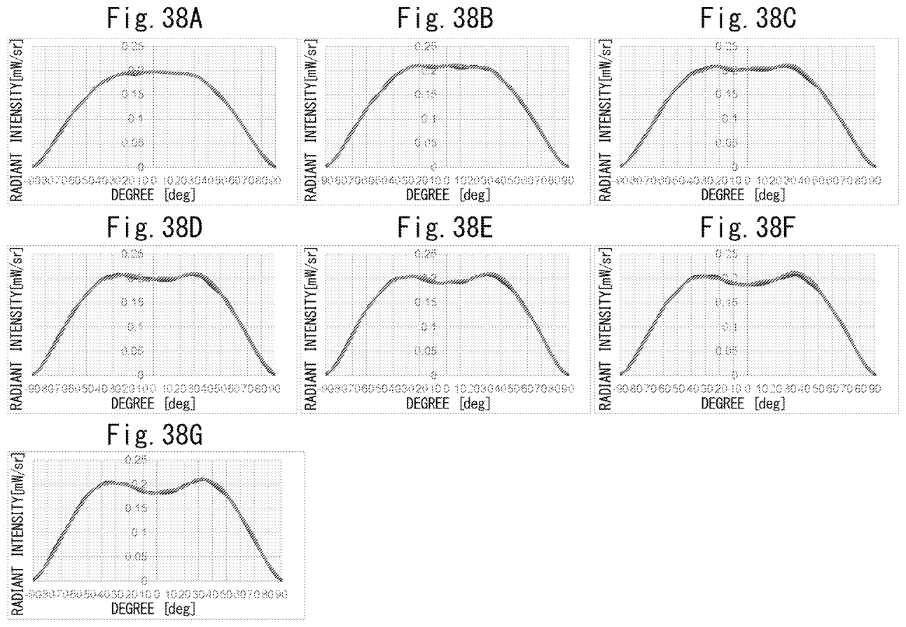

FIG. 38A to 38G are each a diagram showing directivity when the separation distance between the front end of the first frame body 851 and the end portion of the light emitting element 14 is changed. In FIG. 38A to 38G, the horizontal axis represents the angle and the vertical axis represents the radiant intensity. The simulation shown in FIG. 38A to 38G was performed by using LightTools manufactured by Synopsys, Inc as a simulator. FIG. 38A shows the directivity when the separation distance between the front end of the first frame portion 851 and the end portion of the light emitting element 14 is 80 μm and FIG. 38B shows the directivity when the separation distance between the front end of the first frame portion 851 and the end portion of the light emitting element 14 is 180 μm. FIG. 38C shows the directivity when the separation distance between the front end of the first frame portion 851 and the end portion of the light emitting element 14 is 280 μm and FIG. 38D shows the directivity when the separation distance between the front end of the first frame portion 851 and the end portion of the light emitting element 14 is 380 μm. FIG. 38E shows the directivity when the separation distance between the front end of the first frame portion 851 and the end portion of the light emitting element 14 is 480 μm and FIG. 38F shows the directivity when the separation distance between the front end of the first frame portion 851 and the end portion of the light emitting element 14 is 580 μm. FIG. 38G shows the directivity when the separation distance between the front end of the first frame portion 851 and the end portion of the light emitting element 14 is 680 μm.

As shown in FIG. 38A, when the separation distance between the front end of the first frame portion 851 and the end portion of the light emitting element 14 is 80 μm, the radiant intensity is in the range of ±1% of the radiant intensity at 0° in a case where the angle is ±25° and the radiant intensity takes the maximum. Further, the radiant intensity is in the range of ±5% of the radiant intensity at 0° in a case where the angle is ±35° and flat directivity of light is obtained. When the separation distance between the front end of the first frame portion 851 and the end portion of the light emitting element 14 is 80 μm, the maximum value of the radiant intensity increases 1% from the radiant intensity at 0°. As shown in FIG. 38B, when the separation distance between the front end of the first frame portion 851 and the end portion of the light emitting element 14 is 180 μm, the radiant intensity is in the range of ±1% of the radiant intensity at 0° in a case where the angle is ±25° and the radiant intensity takes the maximum. Further, the radiant intensity is in the range of ±5% of the radiant intensity at 0° in a case where the angle is ±35° and flat directivity of light is obtained. When the separation distance between the front end of the first frame portion 851 and the end portion of the light emitting element 14 is 180 μm, the maximum value of the radiant intensity increases 1% from the radiant intensity at 0°. As shown in FIG. 38C, when the separation distance between the front end of the first frame portion 851 and the end portion of the light emitting element 14 is 280 μm, the radiant intensity takes the maximum in a case where the angle is ±25°. Further, the radiant intensity is in the range of ±5% of the radiant intensity at 0° in a case where the angle is ±40° and flat directivity of light is obtained. When the separation distance between the front end of the first frame portion 851 and the end portion of the light emitting element 14 is 280 μm, the maximum value of the radiant intensity increases 4% from the radiant intensity at 0°.

As shown in FIG. 38D, when the separation distance between the front end of the first frame portion 851 and the end portion of the light emitting element 14 is 380 μm, the radiant intensity takes the maximum in a case where the angle is between −35° and −25° and between +25° and +35°. When the separation distance between the front end of the first frame portion 851 and the end portion of the light emitting element 14 is 380 μm, the maximum value of the radiant intensity increases 6% from the radiant intensity at 0°. As shown in FIG. 38E, when the separation distance between the front end of the first frame portion 851 and the end portion of the light emitting element 14 is 480 μm, the radiant intensity takes the maximum in a case where the angle is ±30°. When the separation distance between the front end of the first frame portion 851 and the end portion of the light emitting element 14 is 480 μm, the maximum value of the radiant intensity increases 10% from the radiant intensity at 0°. As shown in FIG. 38F, when the separation distance between the front end of the first frame portion 851 and the end portion of the light emitting element 14 is 580 μm, the radiant intensity takes the maximum in a case where the angle is ±35°. When the separation distance between the front end of the first frame portion 851 and the end portion of the light emitting element 14 is 580 μm, the maximum value of the radiant intensity increases 14% from the radiant intensity at 0°. As shown in FIG. 38G, when the separation distance between the front end of the first frame portion 851 and the end portion of the light emitting element 14 is 680 μm, the radiant intensity takes the maximum in a case where the angle is ±35°. When the separation distance between the front end of the first frame portion 851 and the end portion of the light emitting element 14 is 680 μm, the maximum value of the radiant intensity increases 16% from the radiant intensity at 0°.

In the light emitting device 8, when the maximum value of the radiant intensity increases 5% or more from the radiant intensity at 0°, variations are felt as the light output, and therefore, not preferable. In the embodiments shown in FIG. 38A to FIG. 38C, the maximum value of the radiant intensity is less than 5% from the radiant intensity at 0°, and therefore, good directivity is obtained. On the other hand, in the comparative examples shown in FIG. 38D to FIG. 38G, the maximum value of the radiant intensity is 5% or more from the radiant intensity at 0°, and therefore, good directivity is not obtained.

It should be understood that a person skilled in the art can make various changes, substitutions, and modifications to the present invention without departing from the spirit and scope of the present invention. For example, the processing of each unit described above may be performed in a different order as appropriate in the scope of the present invention. Further, the embodiments and modification examples described above may be performed in combination as appropriate in the scope of the present invention.

What is claimed is:

1. A light emitting device comprising:
a substrate;
a light emitting element arranged on the top surface of the substrate;
a frame body arranged on the top surface of the substrate so as to surround the light emitting element and reflecting light from the light emitting element; and
a sealing material arranged inside the frame body and sealing the light emitting element, wherein
the frame body at least has a first frame portion having a first inner circumferential curved surface protruding to the side of the light emitting element and a second frame portion having a second inner circumferential curved surface protruding to the side of the light emitting element,
the first inner circumferential curved surface and the second inner circumferential curved surface each have the shape of a cross section convex upward, and
a connection portion of the first frame portion and the second frame portion is arranged so as to have the same height as that of the top surface of the light emitting element.

2. The light emitting device according to claim 1, wherein
an inclination angle of the first inner circumferential curved surface in the connection portion is smaller than an inclination angle of the second inner circumferential curved surface in the connection portion.

3. The light emitting device according to claim 1, wherein
a difference between the height of the connection portion from the surface of the substrate and the height of the top surface of the light emitting element from the surface of the substrate is less than or equal to ±10% of the height of the top surface of the light emitting element from the surface of the substrate.

4. The light emitting device according to claim 1, wherein
a distance from the light emitting element to the connection portion is less than or equal to 300 μm.

5. The light emitting device according to claim 1, wherein
a ratio of the height of the second frame portion to the distance from the light emitting element to the connection portion is not less than 0.2 and not more than 1.5.

6. The light emitting device according to claim 1, wherein
the second frame portion is formed thicker than the first frame portion and covers the top portion and the outer circumferential surface of the first frame portion.

7. The light emitting device according to claim 1, wherein
the first frame portion and the second frame portion include resin and titanium oxide and
in the first frame portion and the second frame portion, the content of the titanium oxide with the resin taken as a reference is not less than 30 phr and not more than 130 phr.

8. The light emitting device according to claim 1, further comprising:
an electrically conductive wiring pattern arranged so as to be surrounded by the frame body on the top surface of the substrate and reflecting light from the light emitting element, wherein
the light emitting element is arranged on the top surface of the wiring pattern and
the frame body covers the outer circumferential portion of the wiring pattern.

9. The light emitting device according to claim 1, wherein
on the substrate, first wiring and second wiring electrically connected to the light emitting element are arrayed along the long-side direction of the substrate as well as the substrate has the shape of a rectangular plane,
the width of the frame body arranged at both ends in the long-side direction of the substrate is greater than the width of the frame body arranged at both ends in the short-side direction of the substrate, and
the top surface of the sealing material has the shape of a square plane.

10. The light emitting device according to claim 9, wherein
a separation distance between the front end of the first frame portion arranged in the long-side direction of the substrate and the light emitting element is longer than a separation distance between the front end of the first frame portion arranged in the short-side direction of the substrate and the light emitting element.

11. The light emitting device according to claim 1, wherein
in the short-side direction, a length obtained by adding a separation distance between the front end of one of the pair of the first frame portions facing each other and the end portion of the substrate and a separation distance between the front end of the other of the pair and the end portion of the substrate is longer than a length obtained by adding a separation distance between the front end of one of the pair of the first frame portions facing each other and the light emitting element and a separation distance between the front end of the other of the pair and the light emitting element.

12. The light emitting device according to claim 1, wherein
the frame body includes a base resin, first particle diameter fillers, and second particle diameter fillers,
the frame body contains the first particle diameter fillers of 10 to 50 wt % with respect to the base resin,
the average particle diameter of the first particle diameter fillers is 1 to 100 μm,
the frame body contains the second particle diameter fillers of 4 to 15 wt % with respect to the base resin,
the average particle diameter of the second particle diameter fillers is 1 to 500 μm, and
the frame body has a diced lateral surface.

13. The light emitting device according to claim 12, wherein
in the frame body, a ratio of the width of the bottom surface to the height of the frame body is 0.6 to 4.0.

14. The light emitting device according to claim 12, wherein
hardness of the frame body is Shore D 65 to D74.

15. The light emitting device according to claim 12, wherein
the frame body further includes titanium oxide and
the frame body contains the titanium oxide of 10 to 70 wt % with respect to the base resin.

16. A light emitting device comprising:
a substrate on the top surface of which a wiring pattern in which a concave portion is formed is arranged;
a light emitting element arranged on the top surface of the substrate;
a frame body arranged on the top surface of the substrate so as to surround the light emitting element; and
a sealing material arranged inside the frame body and sealing the light emitting element, wherein
the frame body at least has a first frame portion having a first inner circumferential curved surface protruding the side of the light emitting element and a second frame portion having a second inner circumferential curved surface protruding to the side of the light emitting element,
the first inner circumferential curved surface and the second inner circumferential curved surface each have the shape of a cross section convex upward,
a connection portion of the first frame portion and the second frame portion is arranged so as to have the same height as that of the top surface of the light emitting element,
on the substrate, first wiring and second wiring electrically connected to the light emitting element are arrayed along the long-side direction of the substrate as well as the substrate has the shape of a rectangular plane,
the width of the frame body arranged at both ends in the long-side direction of the substrate is greater than the width of the frame body arranged at both ends in the short-side direction of the substrate, and
the pair of the first frame portions arranged in the long-side direction of the substrate is arranged so as to cover the concave portion.

17. A light emitting device comprising:
a substrate;
an LED arranged on the top surface of the substrate;
a frame body arranged on the top surface of the substrate so as to surround the LED and reflecting light from the LED; and
a sealing material arranged inside the frame body and sealing the LED, wherein the frame body at least has a first frame portion arranged on the substrate and having a first inner circumferential curved surface protruding to the side of the LED and a second frame portion arranged on the first frame portion and having a second inner circumferential curved surface protruding to the side of the LED,
the frame body is a white resin including fine particles of resin and titanium oxide,
the LED is a blue LED, a purple LED, or a near-ultraviolet LED,
on the substrate, first wiring and second wiring electrically connected to the LED are arrayed along a first direction of the substrate, and
the width of the frame body arranged at both ends in the first direction of the substrate is greater than the width of the frame body arranged at both ends in a second direction perpendicular to the first direction of the substrate.
